(19) United States
(12) Patent Application Publication
(10) Pub. No.: US 2023/0227961 A1
(43) Pub. Date: Jul. 20, 2023

(54) MASK ASSEMBLY AND METHOD FOR MANUFACTUFING THE SAME AND METHOD FOR MANUFACTUFING DISPLAY PANEL USING THE MASK ASSEMBLY

(71) Applicant: Samsung Display Co., Ltd., Yongin-si (KR)

(72) Inventors: JAEMIN HONG, Seongnam-si (KR); SUNG JIN NA, Asan-si (KR); HEESEAK NOH, Cheonan-si (KR); SEONGCHEOL LEE, Seoul (KR)

(73) Assignee: Samsung Display Co., Ltd., Yongin-si (KR)

(21) Appl. No.: 18/076,487

(22) Filed: Dec. 7, 2022

(30) Foreign Application Priority Data
Jan. 19, 2022 (KR) 10-2022-0007840

(51) Int. Cl. C23C 14/04; H10K 71/16; H10K 71/00

(52) U.S. Cl. CPC C23C 14/042; H01L 51/0011; H01L 51/56

(57) ABSTRACT

A mask assembly includes a frame including long side portions extending in a first direction and spaced apart from each other in a second direction intersecting the first direction, and short side portions connected to the long side portions, the frame defining a frame opening, a first stick extending in the second direction and connected to the frame, a first mask sheet defining first deposition openings and connected to the first stick and the frame, at least part of the first deposition openings arranged in the first direction and overlapping the frame opening in a plan view, and a second mask sheet defining second deposition openings and connected to the first stick and the frame, at least part of the second mask sheet arranged in the first direction and overlapping the frame opening in a plan view.

### CROSS-REFERENCE TO RELATED APPLICATIONS

This U.S. non-provisional patent application claims priority to and benefits of Korean Patent Application No. 10-2022-0007840 under 35 U.S.C. § 119, filed on Jan. 19, 2022, in the Korean Intellectual Property Office (KIPO), the entire contents of which are incorporated herein by reference.

### BACKGROUND

The disclosure herein relates to a mask assembly, a method for manufacturing the mask assembly, and a method for manufacturing a display panel using the mask assembly, and more particularly, to a mask assembly that is capable of forming a deposition layer commonly overlapping pixels, a method for manufacturing the mask assembly, and a method for manufacturing a display panel using the mask assembly.

A display panel includes pixels. Each of the pixels includes a driving element such as a transistor and a display element such as an organic light emitting element. The display element may be formed by laminating electrodes and various functional layers on a substrate.

The functional layers constituting the display element may be formed through a deposition process using a mask having a through-opening defined therein. In this case, a shape of each of the patterned functional layers may be controlled according to a shape of an open area of the mask. Thus, to improve deposition quality of the patterned functional layers, it is necessary to develop a technique for a mask assembly and a method of manufacturing the mask with high precision.

### SUMMARY

The disclosure provides a mask assembly including an elongated part such as a stick.

The disclosure also provides a method for manufacturing a mask assembly.

The disclosure also provides a method for manufacturing a display panel, which is capable of having deposition precision.

An embodiment of the disclosure provides a mask assembly including a frame including long side portions extending in a first direction and spaced apart from each other in a second direction intersecting the first direction, and short side portions connected to the long side portions, the frame defining a frame opening; a first stick extending in the second direction and connected to the frame; a first mask sheet defining first deposition openings and connected to the first stick and the frame, at least part of the first deposition openings arranged in the first direction and overlapping the frame opening in a plan view; and a second mask sheet defining second deposition openings and connected to the first stick and the frame, at least part of the second mask sheet arranged in the first direction and overlapping the frame opening in a plan view.

In an embodiment, a portion of the first stick may be exposed between the first mask sheet and the second mask sheet.

In an embodiment, the long side portions include stick grooves, and the first stick may be inserted into the stick grooves.

In an embodiment, the first stick may be disposed on a rear surface of the first mask sheet and a rear surface of the second mask sheet.

In an embodiment, the first stick may be disposed on a front surface of the first mask sheet and a front surface of the second mask sheet.

In an embodiment, each of the first mask sheet and the second mask sheet may have a thickness in a range of about 50 um to about 300.

In an embodiment, the first stick may have a thickness in a range of about 50 um to about 300, and the first stick in the first direction may have a width in a range of about 1 mm to about 5.

In an embodiment, each of the first mask sheet, the second mask sheet, the first stick, and the frame may include an invar.

In an embodiment, the mask assembly may further include a second stick extending in the second direction and spaced apart from the first stick in the first direction; and a third mask sheet defining third deposition openings and connected to the second stick and the frame, the third deposition openings arranged in the first direction and overlapping the frame opening in a plan view. The second mask sheet may be disposed between the first mask sheet and the third mask sheet, and a portion of the second stick may be exposed between the second mask sheet and the third mask sheet.

In an embodiment, each of the first to third mask sheets may include sides spaced apart from each other in the first direction and other sides spaced apart from each other in the second direction, one of the sides of the first mask sheet may be connected to the first stick, another one of the sides is connected to an overlapping one side portion of the short side portions, and each of the other side may be connected to an overlapping one of the long side portions, one of the sides of the third mask sheet may be connected to the second stick, another one of the sides may be connected to an overlapping one of the short side portions, and each of the other sides may be connected to an overlapping one of the long side portions, and one of the sides of the second mask sheet may be connected to the first stick, another one of the sides may be connected to the second stick, and each of the other sides may be connected to an overlapping one of the long side portions.

In an embodiment, the mask assembly may further include first welding protrusions respectively disposed on a front surface of each of the first mask sheet and the second mask sheet and a front surface of the second mask sheet and the third mask sheet, the front surface of each of the first mask sheet and second mask sheet overlapping the first stick in a plan view, the front surface of each of the second mask sheet and third mask sheet overlapping the second stick in a plan view; and second welding protrusions respectively disposed on the front surfaces of the first to third mask sheets overlapping the frame in a plan view.

In an embodiment, at least one of the first deposition openings, the second deposition openings, and the third deposition openings may be arranged in n rows×m columns in the first direction and the second direction, n and m being natural numbers and at least one of n and m being greater than or equal to 2.

In an embodiment, a width of each of the first mask sheet and the second mask sheet in the first direction may be less than a width of each of the first mask sheet and the second mask sheet in the second direction.

In an embodiment of the disclosure, a method for manufacturing a mask assembly includes providing a frame defining a frame opening, a width of the frame in a first direction is greater than a width of the frame in a second direction intersecting the first direction; providing mask sheets and at least one stick on the frame, the at least one stick supporting two adjacent ones of the mask sheets; connecting the mask sheets adjacent to the at least one stick to the at least one stick in a state, in which the mask sheets and the at least one stick are tensioned to sides in the second direction; tensioning the coupling sheet to sides in the first direction and tensioning the coupling sheet to the sides in the second direction by applying tensile force; connecting the tensioned coupling sheet to the frame; releasing the tensile force applied to the coupling sheet to which the frame is connected; and additionally processing the coupling sheet from which the tensile force is released.

The method further includes forming pre-deposition openings in each of the mask sheets, and the forming of the pre-deposition openings is performed before the providing of the mask sheets on the frame or performed between the tensioning of the coupling sheet and the connecting of the tensioned coupling sheet to the frame.

In an embodiment, the mask sheets may include first to third mask sheets, the at least one stick may include a first stick overlapping the first mask sheet and the second mask sheet in a plan view; and a second stick overlapping the second mask sheet and the third mask sheet in a plan view, the providing of the mask sheets and the at least one stick may include sequentially providing the first mask sheet, the first stick, the second mask sheet, the second stick, and the third mask sheet.

In an embodiment, the pre-deposition openings may be arranged to be spaced apart from each other in the first direction and the second direction.

In an embodiment, in the providing of the mask sheets and the at least one stick, the mask sheets and the at least one stick may be provided to sides in the second direction in a state in which each of the mask sheets and the at least one stick is tensioned.

In an embodiment, the forming of the coupling sheet may include welding each of the mask sheets to a corresponding one of the at least one stick.

In an embodiment, the connecting of the tensioned coupling sheet to the frame may include welding the coupling sheet to the frame.

In an embodiment, the method may further include adjusting the tensile force applied to the coupling sheet between the tensioning of the coupling sheet and the connecting of the tensioned coupling sheet to the frame.

In an embodiment, the forming of the pre-deposition openings may be performed by a laser process.

In an embodiment, the additionally processing of the coupling sheet from which the tensile force is released may include cutting the mask sheets to remove an exposed area from at least the frame.

In an embodiment, the additionally processing of the coupling sheet from which the tensile force is released may include trimming the pre-deposition openings to form deposition openings.

In an embodiment, each of the deposition openings may have a surface area greater than a surface area of each of the pre-deposition openings.

In an embodiment of the disclosure, a method for manufacturing a mask assembly includes forming a deposition layer on a deposition substrate with the mask assembly, wherein the mask assembly includes a frame including long side portions extending in a first direction and spaced apart from each other in a second direction intersecting the first direction; and short side portions connected to the long side portions, the frame defining a frame opening; a first stick extending in the second direction and connected to the frame; a first mask sheet defining first deposition openings arranged to be spaced apart from each other in the first direction and overlapping the frame opening in a plan view, the first mask sheet being connected to the first stick and the frame; and a second mask sheet defining second deposition openings arranged to be spaced apart from each other in the first direction and overlapping the frame opening in a plan view, the second mask sheet being connected to the first stick and the frame.

In an embodiment, the deposition substrate may include unit areas and a non-deposition area adjacent to the unit areas, each of the unit areas may overlap a corresponding opening of the first deposition openings and the second deposition openings in a plan view, and the non-deposition area may overlap the first mask sheet, the first stick, and the second mask sheet in a plan view.

In an embodiment, light emitting elements may be disposed in each of the unit areas, each of the light emitting elements may include a first electrode, a second electrode, and a light emitting layer between the first electrode and the second electrode, the light emitting layer may correspond to the deposition layer formed by deposition vapor passing through the corresponding opening, and the light emitting layer of each of the light emitting elements may have an integral shape.

In an embodiment, light emitting elements may be disposed in each of the unit areas, and at least one inorganic layer may be disposed on a lower portion or an upper portion of each of the light emitting elements, the at least one inorganic layer may correspond to the deposition layer formed by deposition vapor passing through the corresponding opening, and the at least one inorganic layer may have an integral shape.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain principles of the disclosure. In the drawings:

FIG. 1A is a schematic cross-sectional view of an ink jet apparatus according to an embodiment of the disclosure;

FIG. 1B is a plan view of a deposition substrate according to an embodiment of the disclosure;

FIG. 2 is a schematic perspective view of a display panel manufactured through a deposition apparatus according to an embodiment of the disclosure;

FIG. 3 is a schematic cross-sectional view of the display panel according to an embodiment of the disclosure;

FIG. 4A is a schematic plan view of a mask assembly according to an embodiment of the disclosure;

FIG. 4B is a schematic cross-sectional view taken along line I-I′ of FIG. 4A;

FIG. 4C is a schematic exploded perspective view of the mask assembly according to an embodiment of the disclosure;

FIG. 5 is a schematic exploded cross-sectional view of the mask assembly according to an embodiment of the disclosure;

FIG. 6 is a schematic exploded cross-sectional view of the mask assembly according to an embodiment of the disclosure;

FIGS. 7A to 7N are schematic plan views illustrating a method for manufacturing a mask assembly according to an embodiment of the disclosure; and

FIGS. 8A to 8M are schematic plan views illustrating a method for manufacturing a mask assembly according to an embodiment of the disclosure.

### DETAILED DESCRIPTION OF THE EMBODIMENTS

In this specification, it will also be understood that when one component (or region, layer, portion) is referred to as being “on,” “connected to,” or “coupled to” another component, it can be directly disposed/connected/coupled on/to the one component, or an intervening third component may also be present.

Like reference numerals refer to like elements throughout. Also, in the figures, the thickness, ratio, and dimensions of components may be exaggerated for clarity of illustration. The term “and/or” includes any and all combinations of one or more of the associated components.

It will be understood that although the terms such as “first” and “second,” and the like are used herein to describe various elements, these elements should not be limited by these terms. The terms are only used to distinguish one component from other components. For example, a first element referred to as a first element in an embodiment can be referred to as a second element in another embodiment without departing from the scope of the appended claims. The terms a singular form may include plural forms unless referred to the contrary.

Also, “under,” “below,” “above,” “upper,” and the like are used for explaining relation association of the elements illustrated in the drawings. The terms may be a relative concept and described based on directions expressed in the drawings.

The meaning of “include” or “comprise” specifies a property, a fixed number, a process, an operation, an element, a component or a combination thereof, but does not exclude other properties, fixed numbers, processes, operations, elements, components or combinations thereof.

The term “overlap” as used herein may mean that at least part of a first object faces at least part of a second object in a given direction or given view.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The term “and/or” includes all combinations of one or more of which associated configurations may define. For example, “A and/or B” may be understood to mean “A, B, or A and B.”

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

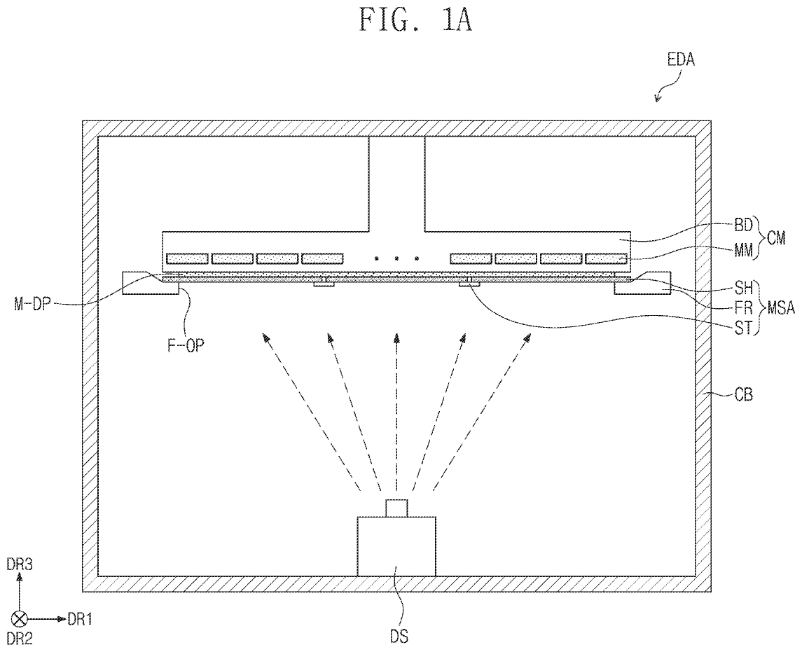

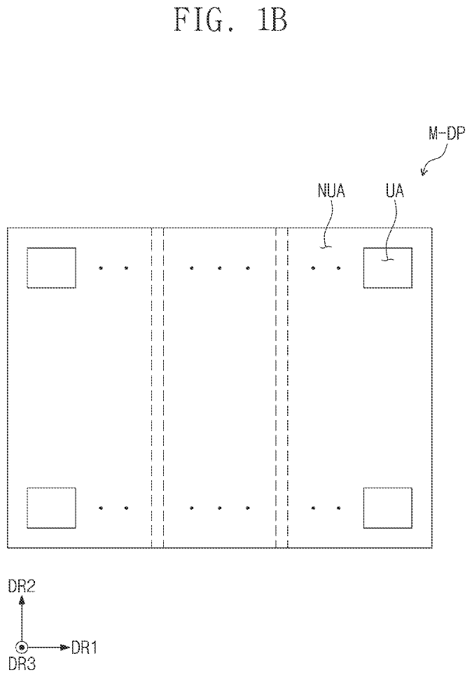

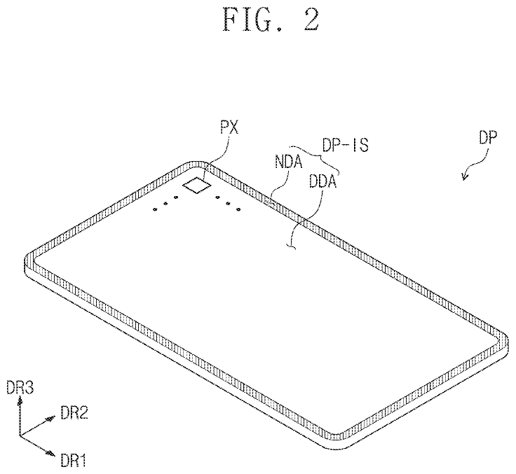

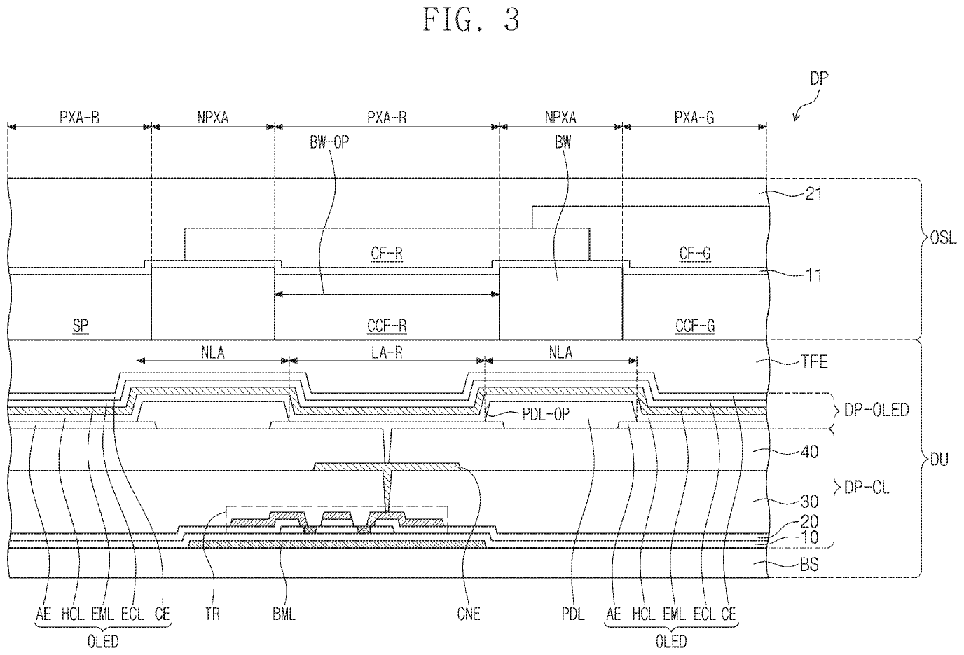

FIG. 1A is a schematic cross-sectional view of an ink jet apparatus according to an embodiment of the disclosure. FIG. 1B is a schematic plan view of a deposition substrate according to an embodiment of the disclosure. FIG. 2 is a schematic perspective view of a display panel manufactured by a deposition apparatus according to an embodiment of the disclosure. FIG. 3 is a schematic cross-sectional view of a display panel according to an embodiment of the disclosure.

Referring to FIG. 1A, a deposition apparatus EDA according to an embodiment of the disclosure may include a deposition chamber CB, a fixing member CM, a deposition source DS disposed inside the deposition chamber CB, and a mask assembly MSA disposed inside the deposition chamber CB. Although not shown separately, the deposition apparatus EDA may further include an additional machine for implementing an in-line system.

The deposition chamber CB may set a deposition condition to a vacuum state. The deposition apparatus EDA may further include a machine for converting the deposition chamber CB to a vacuum state during a deposition process.

The deposition chamber CB may include a bottom surface, a ceiling surface, and sidewalls. The bottom surface of the deposition chamber CB may be parallel to a surface defined by a first direction DR1 and a second direction DR2. A third direction DR3 may be indicated as a normal direction of the bottom surface of the deposition chamber CB.

The fixing member CM may be disposed inside the deposition chamber CB, may be disposed on the deposition source DS, and may fix the mask assembly MSA. The fixing member CM may be installed on the ceiling surface of the deposition chamber CB. The fixing member CM may include a jig or a robot arm that holds the mask assembly MSA.

The fixing member CM may include a base part BD and magnetic materials MM coupled to the base part BD. The base part BD may include a plate as a basic structure for fixing the mask assembly MSA, but is not limited thereto. The magnetic materials MM may be disposed inside or outside the base part BD. The magnetic materials MM may fix the mask assembly MSA with magnetic force.

The deposition source DS may evaporate a deposition material so as to be ejected as deposition vapor. The deposition vapor passes through a frame opening F-OP defined in a frame FR and is deposited on a deposition substrate M-DP. The deposition material may include an inorganic material for forming an inorganic layer, a monomer for forming an organic layer, a light emitting material for forming a light emitting layer, and the like.

The mask assembly MSA according to this embodiment may include the frame FR, at least one stick (or elongated part) ST, and mask sheets SH. The mask assembly MSA may be disposed inside the deposition chamber CB, may be disposed on the deposition source DS, and supports the deposition substrate M-DP.

The deposition substrate M-DP may include a base substrate such as a glass substrate or a plastic substrate. The deposition substrate M-DP may include a polymer layer disposed on the base substrate. The polymer layer may correspond to a base layer BS (see FIG. 3) of a display panel DP (see FIG. 3).

Referring to FIG. 1B, the deposition substrate M-DP according to an embodiment may include unit areas UA and a non-deposition area NUA adjacent to the unit area UA. According to an embodiment, a smaller width of a width in the first direction DR1 and a width in the second direction DR2 of the deposition substrate M-DP may be about 1,080 mm or more.

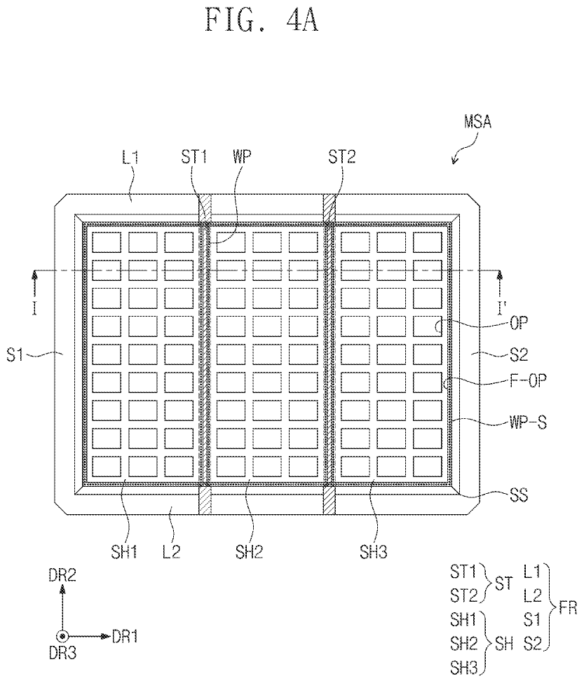

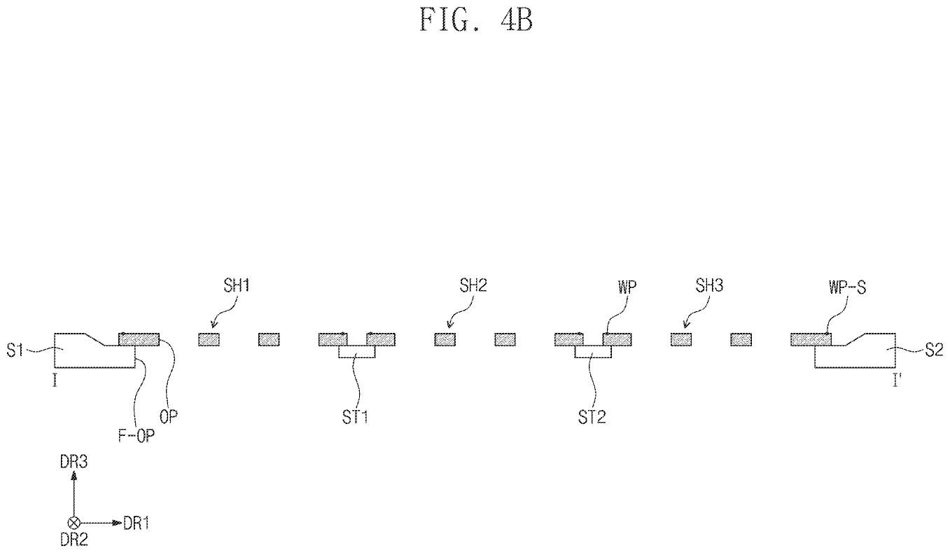

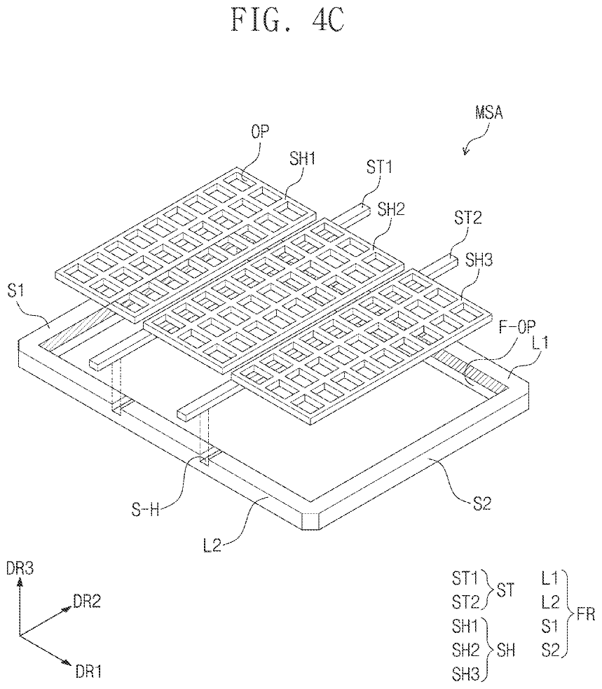

Each of the unit areas UA may overlap an opening corresponding to deposition openings OP (see FIG. 4A) defined in the mask sheets SH to be described later. The non-deposition area NUA may overlap the mask sheets SH and at least one sheet ST.

Each of the unit areas UA may be defined as an area in which a deposition layer is formed using the mask assembly MSA. After a deposition process using the mask assembly MSA and other manufacturing processes are completed, in case that the non-deposition area NUA is cut, each of the unit areas UA may be formed into a display panel DP (see FIG. 2). Thus, the mask assembly MSA according to the disclosure may be provided in the form of an open mask.

As the deposition process progresses, the lamination structure disposed on the base substrate of the deposition substrate M-DP may increase. In other words, the lamination structure disposed on the base substrate in case that an inorganic layer is disposed on the deposition substrate M-DP by using the mask assembly MSA and the lamination structure disposed on the base substrate in case that the light emitting layer is disposed on the deposition substrate M-DP by using the mask assembly MSA may be different from each other.

The deposition openings OP (see FIG. 4A) through which the mask sheets SH pass may be defined in the mask sheets SH. The deposition vapor passing through the frame opening F-OP may pass through the deposition openings OP (see FIG. 4A) and be deposited on the deposition substrate M-DP. Each of the mask sheets SH may have a thickness of about 50 μm or more to about 300 μm or less (or a thickness in a range of about 50 μm to about 300 μm).

FIG. 2 illustrates a display panel DP formed by the deposition apparatus EDA (see FIG. 1A) according to the disclosure.

Referring to FIG. 2, the display panel DP may be a light emitting display panel and may be any of an organic light emitting display panel, an inorganic light emitting display panel, and a quantum-dot display panel.

The display panel DP may display an image through a display surface DP-IS. A top surface of a member disposed at the uppermost side of the display panel DP may be defined as the display surface DP-IS. The member disposed at the uppermost side of the display panel DP may be a window. The display surface DP-IS may be a surface that is parallel to a surface defined by a first direction DR1 and a second direction DR2. A normal direction of the display surface DP-IS, for example, a thickness direction of the display panel DP is indicated as a third direction DR3.

The display panel DP according to the disclosure may provide a large-area display surface DP-IS. Thus, widths of the display panel DP in the first direction DR1 and the second direction DR2 are not limited to any specific one insofar as the display panel DP is applied to a commercially available large-area television.

The display panel DP may include a display area DDA and a non-display area NDA. The non-display area NDA may be defined along an edge of the display surface DP-IS. The non-display area NDA may be adjacent to or may surround the display area DDA. In an embodiment of the disclosure, the non-display area NDA may be omitted or may be disposed at only one side of the display area DDA.

The display panel DP may include pixels PX. Pixel areas PXA-R, PXA-G, and PXA-B (see FIG. 3) providing light generated from the pixels PX may be disposed on the display area DDA, and a driving element for driving the pixels PX and lines connected to the pixels PX may be disposed on the non-display area NDA.

FIG. 3 illustrates a schematic cross-sectional view of the display panel DP manufactured using the deposition apparatus EDA (see FIG. 1A) according to an embodiment of the disclosure.

FIG. 3 illustrates, as an example, a cross-sectional view of the display panel DP in a state in which the deposition process and a subsequent process(es) are performed on the unit areas UA (see FIG. 1B) of the deposition substrate M-DP (see FIG. 1B) and the non-deposition area NUA (see FIG. 1B) is removed so that the unit areas UA are divided as individual parts.

A display part DU may include a base layer BS, a circuit element layer DP-CL disposed on the base layer BS, a display element layer DP-OLED, and a thin film encapsulation layer TFE. The base layer SUB may include a synthetic resin film. The synthetic resin layer may include a thermosetting resin. The synthetic resin layer may be a polyimide resin layer, and the material thereof is not particularly limited.

The circuit element layer DP-CL may include at least one transistor TR, a driving circuit, and signal lines of the pixel. The display element layer DP-OLED may include a light emitting element OLED disposed for each pixel. The light emitting element OLED may include an organic light emitting diode or an inorganic light emitting diode. The thin film encapsulation layer TFE may include at least one inorganic layer and organic layer that seal the light emitting element OLED.

A light control layer OSL may convert optical properties of source light generated in the light emitting element OLED. The light control layer OSL may include a light conversion pattern that converts the source light into light having a different color and a scattering pattern that scatters the source light.

At least one transistor TR and first to fourth insulating layers 10 to 40 may be disposed on the base layer BS. A semiconductor pattern and conductive patterns provided in the transistor TR may be disposed between the first to fourth insulating layers 10 to 40. According to an embodiment, a light blocking pattern BML overlapping the semiconductor pattern of the transistor TR and disposed between the base layer BS and the first insulating layer 10 may be further provided.

Each of the first to fourth insulating layers 10 to 40 may be an inorganic layer or an organic layer and may be entirely disposed on at least the display area DDA described with reference to FIG. 2. The first to fourth insulating layers 10 to 40 may be provided by the mask assembly MSA according to the disclosure.

A light emitting element OLED and a pixel defining layer PDL may be disposed on the fourth insulating layer 40. A display opening PDL-OP of the pixel defining layer PDL may expose at least a portion of an anode AE (first electrode). The display opening PDL-OP of the pixel defining layer PDL may define an emission area LA-R. An area in which the pixel defining layer PDL may be disposed may be defined as a non-emission area NLA. The anode AE may be connected to the transistor TR through a connection electrode CNE disposed on the third insulating layer 30.

A hole control layer HCL may be disposed (e.g., commonly disposed) on (or in) the emission area LA-R and the non-emission area NLA. A common layer such as the hole control layer HCL may be disposed in the plurality of pixels PX (see FIG. 2). The hole control layer HCL may include a hole transport layer and a hole injection layer.

A light emitting layer EML may be disposed on the hole control layer HCL. The light emitting layer EML may be disposed on the emission area LA-R and the non-emission area NLA. The light emitting layer EML may generate the source light. The light emitting layer EML may include an organic light emitting material or an inorganic light emitting material. According to the disclosure, the light emitting layer EML may be disposed the pixels PX (see, e.g., FIGS. 2 and 3). An electron control layer ECL is disposed on the light emitting layer EML. The electron control layer ECL may include an electron transport layer and an electron injection layer. A cathode CE (second electrode) is disposed on the electron control layer ECL.

The deposition apparatus EDA according to the disclosure may be used in a process of depositing the hole control layer HCL, the electron control layer ECL, or the light emitting layer EML.

The thin film encapsulation layer TFE is disposed on the cathode CE. The thin film encapsulation layer TFE is disposed in the pixels PX (see FIG. 2). In the embodiment, the thin film encapsulation layer TFE directly covers the cathode CE. The thin film encapsulation layer TFE includes at least an inorganic or organic layer.

In an embodiment of the disclosure, the thin film encapsulation layer TFE may include two inorganic layers and an organic layer disposed between the inorganic layers. In an embodiment of the disclosure, the thin film encapsulation layer TFE may include inorganic layers and organic layers, which are alternately stacked or laminated each other. The deposition apparatus EDA according to the disclosure may be used in the process of depositing the cathode CE or the thin film encapsulation layer TFE.

The light control layer OSL may be disposed on the thin film encapsulation layer TFE. In this embodiment, the light control layer OSL is illustrated to contact (or to be in contact with) the uppermost inorganic layer of the thin film encapsulation layer TFE, but an additional buffer layer may be further disposed between the uppermost inorganic layer of the thin film encapsulation layer TFE and the light control layer OSL.

A partition wall BW (or partition pattern) may be disposed on the thin film encapsulation layer TFE. In this embodiment, the partition wall BW may include a base resin and an additive. The base resin may be made of various resin compositions. The additive may include a coupling agent (or connecting agent) and/or a photoinitiator. The additive may further include a dispersant. The partition wall BW may include a light-transmitting material capable of transmitting the source light.

The partition wall BW may be disposed within the non-emission area NLA. A partition opening BW-OP may be defined in the partition wall BW. The partition opening BW-OP may define pixel areas PXA-R, PXA-G, and PXA-B corresponding to the emission areas LA-R.

Each of light conversion patterns CCF-R and CCF-G and a scattering pattern SP may be disposed inside the corresponding partition opening BW-OP. The first light conversion pattern CCF-R may convert an optical property of first color light. The second light conversion pattern CCF-G may convert the optical property of the first color light. The scattering pattern SP may transmit the first color light.

In this embodiment, the light conversion patterns CCF-R and CCF-G may absorb the first color light generated by the light emitting element OLED to generate light having a different color. In this embodiment, the light generated in the first light conversion pattern CCF-R of the first pixel area PXA-R may be second color light, and the second color light may be red light. The light generated in the second light conversion pattern CCF-G of the second pixel area PXA-G may be third color light, and the third color light may be green light. The scattering pattern SP of the third pixel area PXA-B may transmit the first color light to provide blue light.

Each of the light conversion patterns CCF-R and CCF-G may include a base resin, quantum dots mixed (or dispersed) in the base resin, and scatterers mixed (or dispersed) in the base resin. Although not shown, a black matrix may be disposed on a top surface of the partition wall BW.

A first insulating layer 11 may be disposed on the thin film encapsulation layer TFE. The first insulating layer 11 may be an inorganic layer. In an embodiment of the disclosure, the first insulating layer 11 may be omitted.

Color filters CF-R and CF-G corresponding to the first and second pixel areas PXA-R and PXA-G may be disposed on the first insulating layer 11. The first color filter CF-R may have the above-described second color and transmits the light having the second color. The second color filter CF-G may have the above-described third color and transmit the light having the third color.

The first color filter CF-R may overlap the first pixel area PXA-R and partially overlap a peripheral area NPXA adjacent to the first pixel area PXA-R. The first color filter CF-R may overlap the second color filter CF-G corresponding to the second pixel area PXA-G adjacent within the peripheral area NPXA. In the area on which the first color filter CF-R and the second color filter CF-G overlap each other, external light reflectance may be reduced.

A second insulating layer 21 of the light control layer OSL may be disposed on the first color filter CF-R and the second color filter CF-G. The second insulating layer 21 may include an organic layer and provide a flat surface.

FIG. 4A is a schematic plan view of the mask assembly according to an embodiment of the disclosure. FIG. 4B is a schematic cross-sectional view taken along line I-I′ of FIG. 4A. FIG. 4C is a schematic exploded perspective view of the mask assembly according to an embodiment of the disclosure.

Referring to FIGS. 4A to 4C, the mask assembly MSA according to an embodiment may include a frame FR, mask sheets SH, and at least one stick ST. The frame FR may support the mask sheets SH and the at least one stick ST. The frame FR may include long side portions L1 and L2 and short side portions S1 and S2. The frame FR may include an invar.

Each of the long side portions L1 and L2 may extend in the first direction DR1, and the long side portions L1 and L2 may be spaced apart from each other in the second direction DR2. Each of the short side portions S1 and S2 may extend in the second direction DR2, and the short side portions S1 and S2 may be spaced apart from each other in the first direction DR1. The long side portions L1 and L2 and the short side portions S1 and S2 may be connected to each other to define the frame opening F-OP.

According to an embodiment, stick grooves S-H may be defined in each of the long side portions L1 and L2, respectively. For example, the stick grooves S-H corresponding to the sticks ST1 and ST2 may be defined in the long side portions L1 and L2, respectively and may be disposed to be spaced apart from each other in the first direction DR1 within the corresponding long side portions L1 and L2.

The stick grooves S-H may be defined by recessing the long side portions L1 and L2 in a thickness direction of the frame FR, for example, in the third direction DR3. At least one corresponding stick ST may be coupled to each of the stick grooves S-H.

The at least one stick ST may include a first stick ST1 and a second stick ST2. Each of the first stick ST1 and the second stick ST2 may extend in the second direction DR2, and the first stick ST1 and the second stick ST2 may be spaced apart from each other in the first direction DR1.

At least one stick ST may include an invar. The at least one stick ST may have a thickness of about 50 μm or more and about 300 μm or less, and the at least one stick ST in the first direction DR1 may have a width of about 1 mm or more and about 5 mm or less.

An end of the first stick ST1 may be disposed in any one stick groove S-H defined in the first long side portion L1, and another end of the first stick ST1 may be disposed in any one stick groove S-H defined in the second long side portion L2.

An end of the second stick ST2 may be disposed in another stick groove S-H defined in the first long side portion L1, and another end of the second stick ST2 may be disposed in another stick groove S-H defined in the second long side portion L2.

Thus, the first stick ST1 and the second stick ST2 may be disposed in the corresponding stick grooves S-H so as to be stably coupled (or connected) to the frame FR.

The mask sheets SH may include a first mask sheet SH1, a second mask sheet SH2, and a third mask sheet SH3. The first to third mask sheets SH1, SH2, and SH3 may be arranged to be spaced apart from each other in the first direction DR1. Each of the first to third mask sheets SH1, SH2, and SH3 may include an invar.

Deposition openings OP, through which front and rear surfaces of the corresponding mask sheet pass, may be defined in the first to third mask sheets SH1, SH2, and SH3, respectively.

A deposition opening OP may correspond to a unit area UA illustrated in FIG. 1B. Thus, an organic layer having an integral shape, an inorganic layer having an integral shape, or a light emitting layer having an integral shape, which correspond to the pixels PX (see FIG. 2) of the display panel DP (see FIG. 2), may be provided in a deposition opening OP by the deposition process.

The deposition openings OP defined in the first to third mask sheets SH1, SH2, and SH3 may be spaced apart from each other in the first direction DR1 and the second direction DR2. Although FIG. 4A illustrates, as an example, the deposition openings OP arranged in 3 rows×9 columns, the embodiment of the disclosure is not limited thereto. For example, the deposition openings arranged in n rows×m columns (where at least one of n and m is a natural number greater than or equal to 2) may be defined in each of the first to third mask sheets SH1, SH2, and SH3, and the arrangement of the deposition openings OP may vary according to a product for which the deposition substrate M-DP (see FIG. 1B) is used. According to an embodiment, the shape of each of the deposition openings OP in a plan view may be a square shape or a rectangular shape.

However, the embodiment of the disclosure is not limited thereto, and only a deposition opening OP may be defined in each of the first to third mask sheets SH1, SH2, and SH3 according to an embodiment. For example, a deposition opening OP formed by (or configured by) the short side portions extending in the first direction DR1 and the long side portions extending in the second direction DR2 and connected to the short side portions may be defined in each of the first to third mask sheets SH1, SH2, and SH3. Thus, a total of three deposition openings may be defined in the mask assembly MSA according to an embodiment. Therefore, the mask assembly MSA according to the disclosure may be used in the deposition process for the large-area display panel.

Although FIG. 4A illustrates three mask sheets SH1, SH2, and SH3 and two sticks ST1 and ST2, the embodiment of the disclosure is not limited thereto, and two or four or more mask sheets may be provided. The number of sticks may vary according to the number of mask sheets.

In the mask assembly MSA according to the disclosure, the mask sheets SH and at least one stick ST may be coupled to the frame FR.

One of sides of the first mask sheets SH1, which are spaced apart from each other in the first direction DR1, may be coupled to the first stick ST1, and another thereof may be coupled to the first short side portion S1. One of other sides of the first mask sheet SH1, which are spaced apart from each other in the second direction DR2, may be coupled to the first long side portion L1, and another of the other sides of the first mask sheet SH1 may be coupled to the second long side portion L2.

One of sides of the second mask sheets SH2, which are spaced apart from each other in the first direction DR1, may be coupled to the first stick ST1, and another thereof may be coupled to the second stick ST2. One of other sides of the second mask sheets SH2, which are spaced apart from each other in the second direction DR2, may be coupled to the first long side portion L1, and another thereof may be coupled to the second long side portion L2.

One of sides of the third mask sheets SH3, which are spaced apart from each other in the first direction DR1, may be coupled to the second stick ST2, and another thereof may be coupled to the second short side portion S2. One of other sides of the third mask sheet SH3, which are spaced apart from each other in the second direction DR2, may be coupled to the first long side portion L1, and another of the other sides of the first mask sheet SH1 may be coupled to the second long side portion L2.

The mask sheets SH and the at least one stick ST may be coupled to each other by a welding process. Thus, first welding protrusions WP provided by the welding process may be disposed on the mask sheets SH overlapping the at least one stick ST.

A state in which the mask sheets SH are coupled to the at least one stick ST may be defined as a trimming sheet SS. The trimming sheet SS may be coupled to the frame FR. The trimming sheet SS and the frame FR may be coupled to each other by the welding process. Thus, second welding protrusions WP-S provided by the welding process may be disposed on the mask sheets SH overlapping the frame FR.

According to this embodiment, the at least one stick ST may be exposed from the mask sheets SH. The adjacent mask sheets among the first to third mask sheets SH1, SH2, and SH3 are spaced apart from each other in the corresponding at least one stick ST. For example, the first stick ST1 may be exposed between the first mask sheet SH1 and the second mask sheet SH2. The second stick ST2 may be exposed between the second mask sheet SH2 and the third mask sheet SH3.

In the mask assembly MSA according to the disclosure, the structure in which additional sticks extending in a direction intersecting the at least one stick ST are disposed on the frame FR to fix the first to third mask sheets SH1, SH2, and SH3 to the frame FR, may be omitted. Thus, the mask assembly MSA may include only a type of stick, and a height difference between the additional sticks and the at least one stick ST may be reduced. As a result, a shadow defect phenomenon of the deposition layer may be reduced, and thus, a small number of sticks may be provided to reduce a risk of deposition defects occurring due to stick deformation.

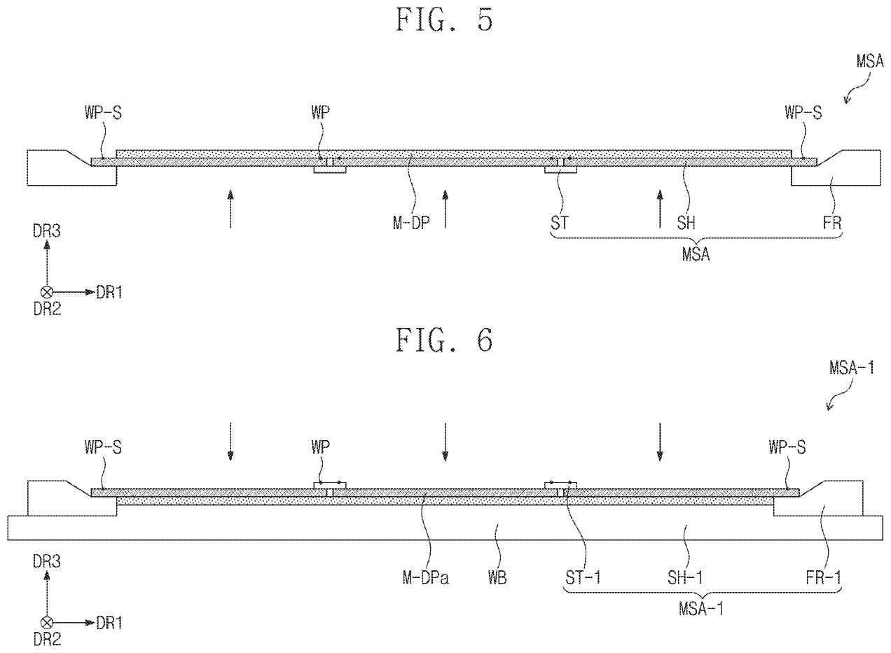

FIG. 5 is a schematic cross-sectional view of the mask assembly according to an embodiment of the disclosure. FIG. 6 is a schematic cross-sectional view of the mask assembly according to an embodiment of the disclosure. The same or similar reference numerals are used for the same components as those of FIGS. 1 to 4B, and thus, their duplicated descriptions will be omitted.

Referring to FIG. 5, the mask assembly MSA according to an embodiment may include a frame FR, mask sheets SH, and at least one stick ST. The at least one stick ST may be disposed in a stick groove S-H defined in the frame FR described with reference to FIG. 4B. The mask sheets SH may be disposed on the at least one stick ST and the frame FR.

According to an embodiment, a deposition substrate M-DP may be disposed on front surfaces of the mask sheets SH. The at least one stick ST may be disposed on rear surfaces of the mask sheets SH.

The frame FR, the mask sheets SH, and the at least one stick ST according to an embodiment may be provided by being coupled to each other by a welding process. First welding protrusions WP provided by the coupling with the at least one stick ST and second welding protrusions WP-S provided by the coupling with the frame FR may be provided on the front surfaces of the mask sheets SH.

The process of depositing the light emitting layer EML described in FIG. 3 may be performed using a mask assembly MSA according to this embodiment. For example, the deposition process may be performed while the deposition substrate M-DP is disposed on the front surfaces of the mask sheets SH. The deposition source DS (see FIG. 1A) may inject deposition vapor onto the rear surfaces of the mask sheets SH. An injection direction of the deposition vapor provided from the deposition source DS (see FIG. 1A) is indicated by an arrow.

Referring to FIG. 6, a mask assembly MSA-1 according to an embodiment may include a frame FR-1, sheets SH-1, and at least one stick ST-1. The at least one stick ST-1 may be disposed in a stick groove S-H defined in the frame FR described with reference to FIG. 4C. The mask sheets SH-1 may be disposed between the at least one stick ST-1 and the frame FR-1.

The mask assembly MSA-1 according to an embodiment may be used in a manufacturing process of forming inorganic layers provided in the display panel DP (see FIG. 3). The mask assembly MSA-1 may be used in a chemical vapor deposition (CVD) process. The type of CVD process is not limited to any specific one.

FIG. 6 illustrates, as an example, only a working substrate WB in a deposition apparatus used in the CVD process. The deposition apparatus used in the CVD process may include an injection part supplying deposition vapor, an exhaust part discharging a reaction gas and byproducts to the outside, a mounting part adjusting a position of the working substrate WB, a power source supplying energy required for reaction, and a regulator regulating a pressure inside a chamber.

According to an embodiment, a deposition substrate M-DPa may be disposed on rear surfaces of the mask sheets SH-1. The at least one stick ST-1 may be disposed on front surfaces of the mask sheets SH-1.

The frame FR-1, the mask sheets SH-1, and the at least one stick ST-1 according to an embodiment may be provided by being coupled to each other by a welding process. First welding protrusions WP provided by the coupling with the mask sheets SH may be provided on the front surface of the stick ST-1, and second welding protrusions WP-S provided by the coupling with the frame FR-1 may be provided on the front surfaces of the mask sheets SH-1.

The process of depositing the inorganic layers provided in the display panel DP (see FIG. 3) described with reference to FIG. 3 may be performed using the mask assembly MSA-1 according to this embodiment. For example, the deposition process may be performed while the deposition substrate M-DPa is disposed on the rear surfaces of the mask sheets SH-1. The injection part of the CVD deposition apparatus may inject the deposition vapor onto the front surfaces of the mask sheets SH-1. An injection direction of the deposition vapor provided from the injection part is indicated by an arrow.

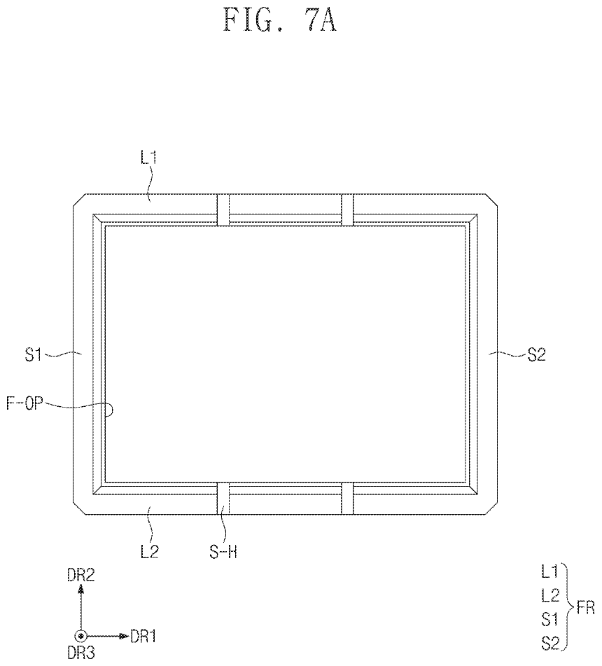

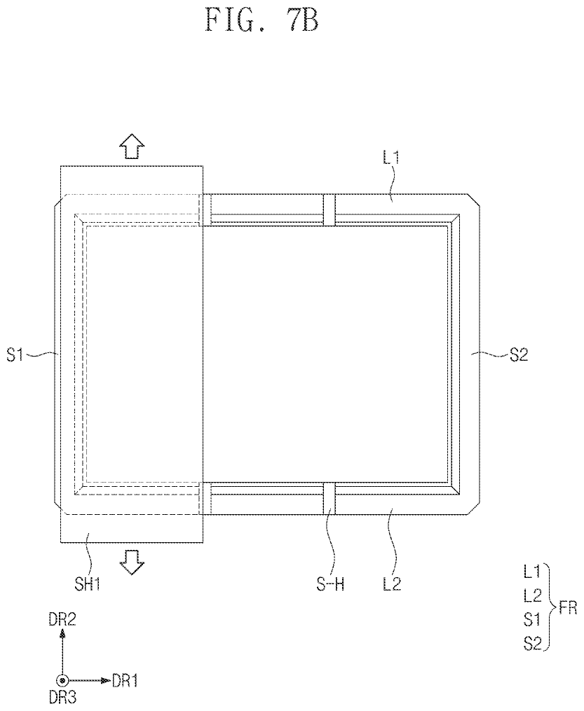

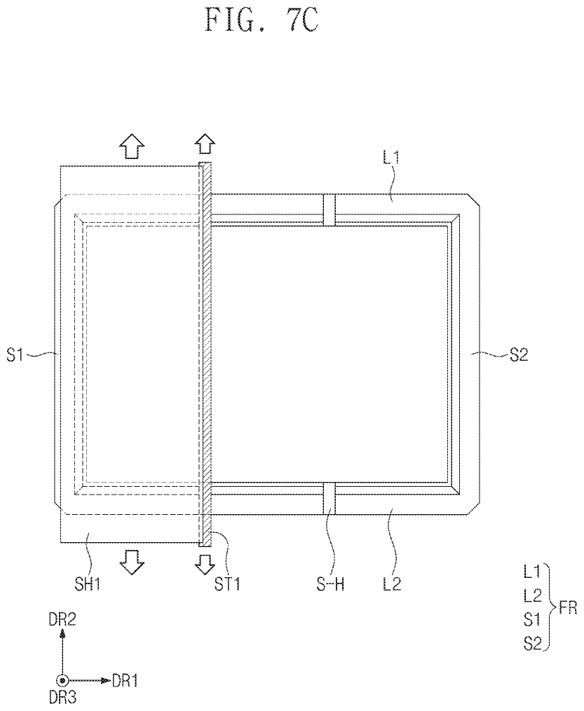

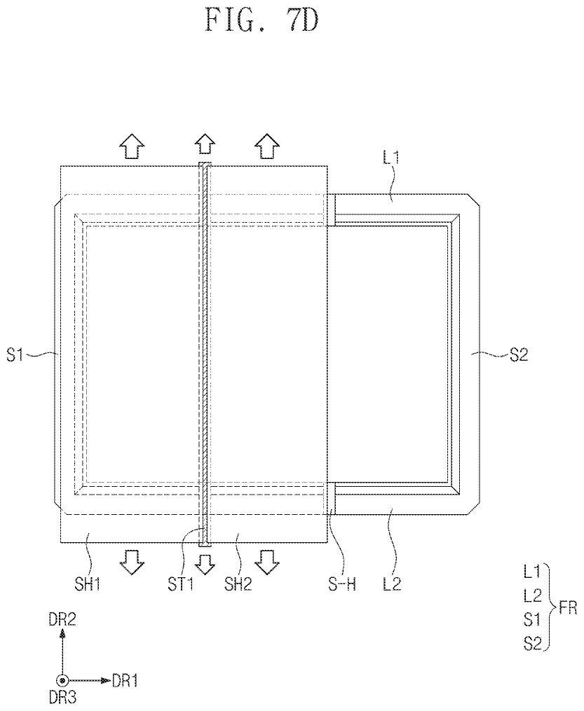

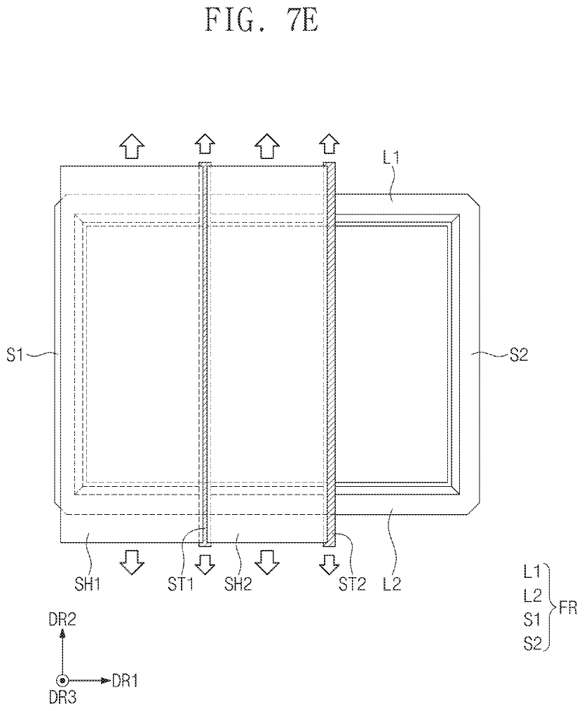

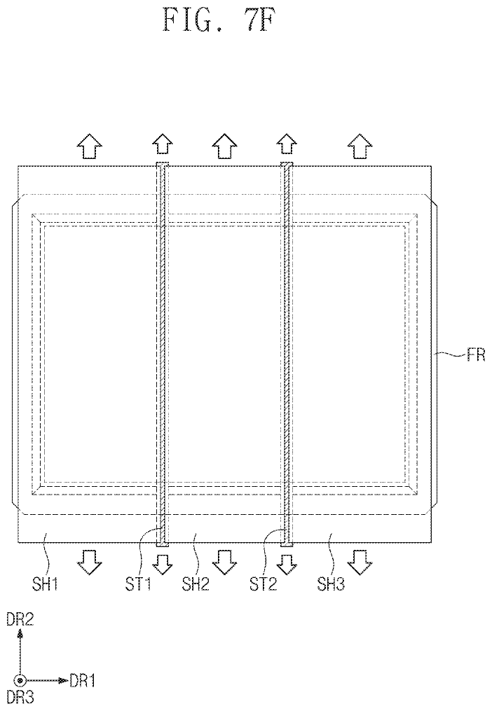

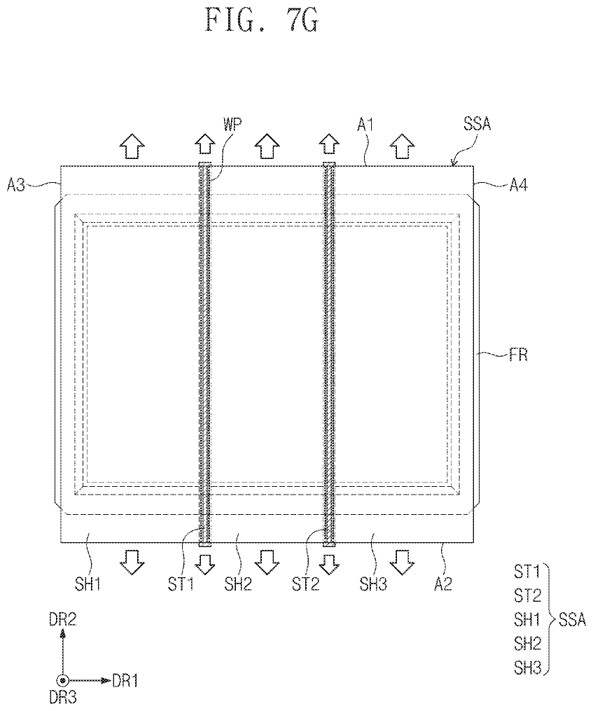

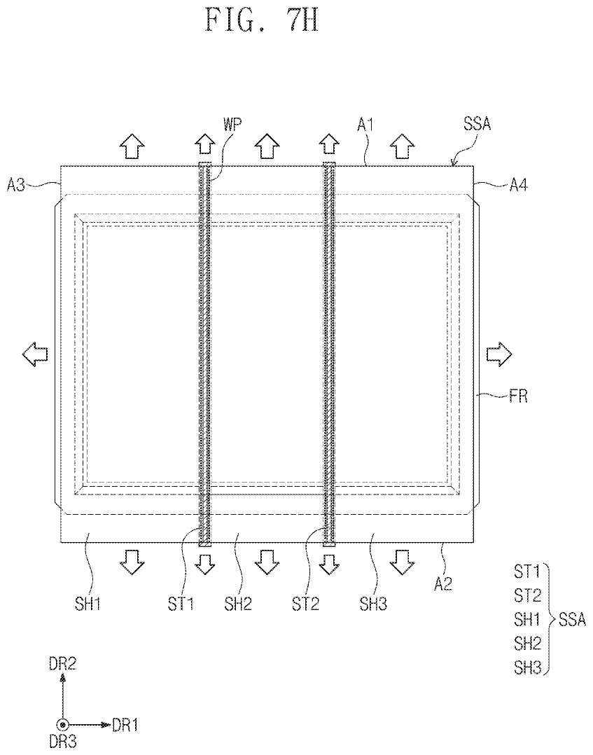

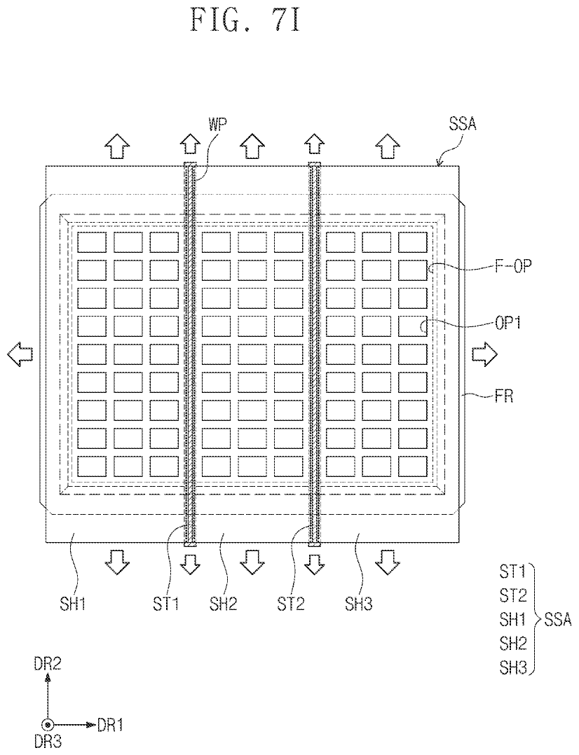

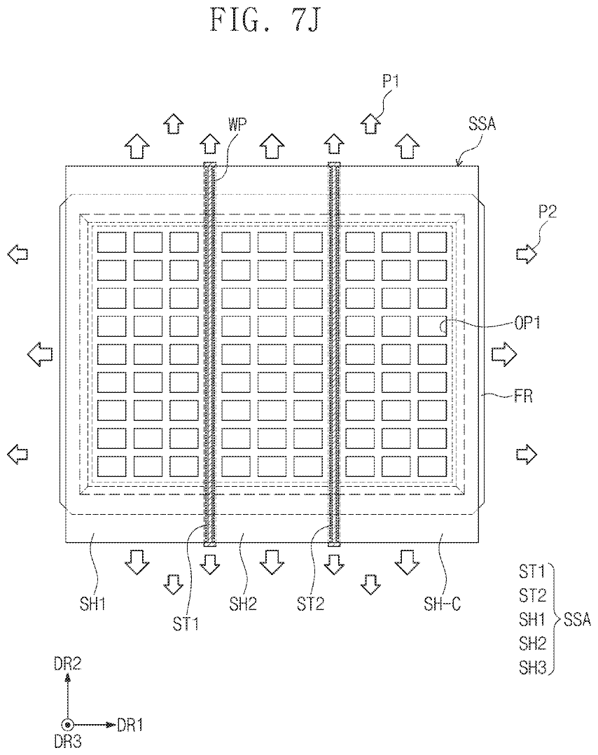

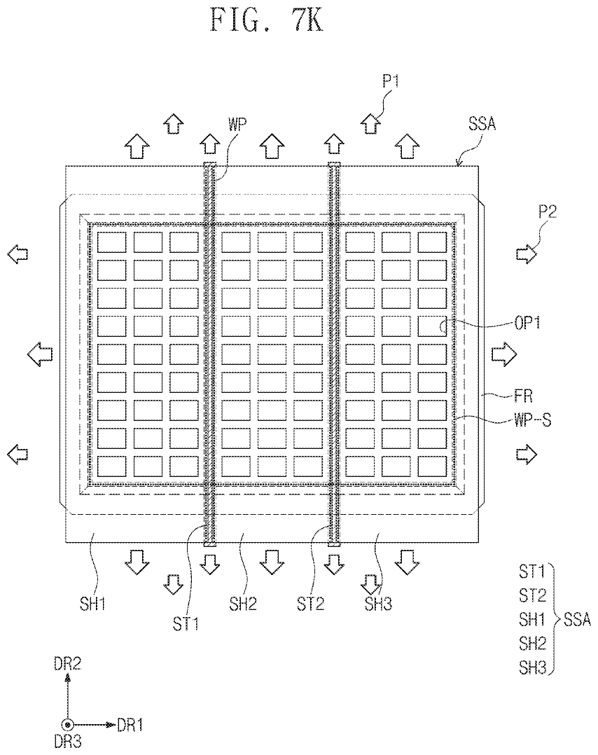

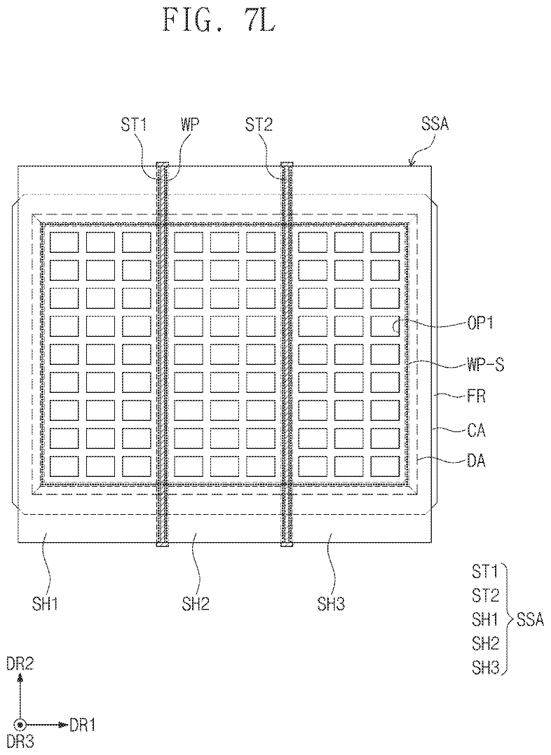

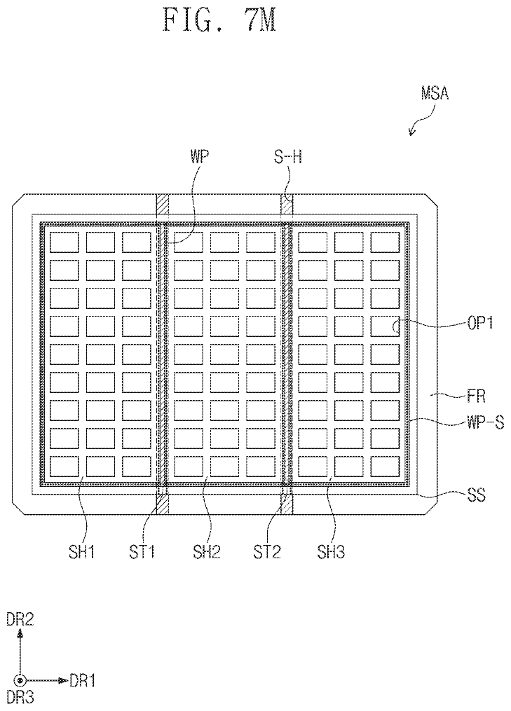

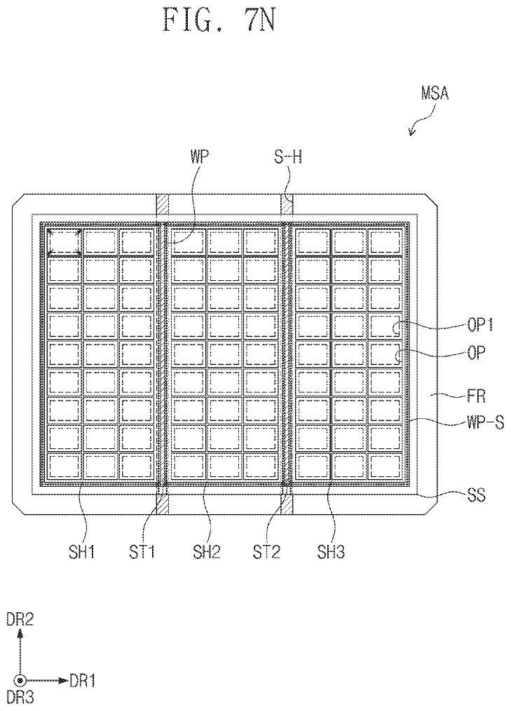

FIGS. 7A to 7N are schematic plan views illustrating a method for manufacturing a mask assembly according to an embodiment of the disclosure. The same or similar reference numerals are used for the same components as those of FIGS. 1 to 4B, and thus, their duplicated descriptions will be omitted.

A method for manufacturing a mask assembly according to an embodiment may include a process of providing a frame in which a frame opening is defined and of which a width in a first direction is greater than that in a second direction intersecting the first direction, a process of providing mask sheets and at least one stick, which supports two adjacent mask sheets among the mask sheets, on the frame, a process of forming a coupling sheet (or connecting sheet) by coupling the mask sheets adjacent to the at least one stick to the at least one stick in a state in which the mask sheets and the at least one stick are tensioned to sides (or both sides) thereof in the second direction, a process of tensioning the coupling sheet to the sides (or the both sides) thereof in the first direction and tensioning the coupling sheet to the sides (or the both sides) in the second direction, a process of coupling the tensioned coupling sheet to the frame, a process of releasing tensile force applied to the coupling sheet, to which the frame is coupled, and a process of additionally processing the coupling sheet from which the tensile force is released and may further include a process of forming pre-deposition openings in the mask sheets, respectively. The process of forming the pre-deposition openings may be performed between the process of tensioning the coupling sheet and the process of coupling the coupling sheet to the frame.

Hereinafter, a method of manufacturing a mask assembly MSA according to an embodiment will be described in more detail with reference to FIGS. 7A to 7N.

Referring to FIG. 7A, a process of providing a frame FR may be performed. The frame FR may include long side portions L1 and L2 and short side portions S1 and S2, which are connected to each other to define a frame opening F-OP.

Thereafter, referring to FIG. 7B, a process of providing a first mask sheet SH1 may be provided.

The first mask sheet SH1 may be provided in a state of being tensioned in the second direction DR2. The first mask sheet SH1 may be tensioned by clamps coupled to ends (or both ends) of the first mask sheet SH1. The tensioning of the mask sheets to be described herein is not limited to any one specific method insofar as it is capable of tensioning the mask sheets. In the drawings, the tensile force applied to a component is illustrated by an arrow.

In case that the first mask sheet SH1 is provided, the first mask sheet SH1 may be disposed with a space (e.g., a predetermined or selectable space) spaced from the frame FR in the third direction DR3.

Thereafter, referring to FIG. 7C, a process of providing a first stick ST1 may be performed.

The first stick ST1 may be provided on the frame FR. The first stick ST1 may be disposed in a space between the first mask sheet SH1 and the frame FR.

The first stick ST1 may be disposed in any a stick groove S-H defined in a first long side portion L1 and any one stick groove S-H defined in a second long side portion L2. Thereafter, a rear surface of the first mask sheet SH1 may be disposed to contact the first stick ST1 and the frame FR.

According to an embodiment, a process of tensioning the first stick ST1 may be performed. The tensioning of the first stick ST1 may be performed in a state in which the first stick ST1 is provided, or may be performed in a state in which the first stick ST1 is tensioned in the second direction DR2. The first stick ST1 may be tensioned by clamps coupled to ends of the first stick ST1.

Thereafter, referring to FIG. 7D, a process of providing a second mask sheet SH2 may be performed. The second mask sheet SH2 may be provided in a state of being tensioned in the second direction DR2. The second mask sheet SH2 may be tensioned by clamps coupled to ends of the second mask sheet SH2.

In case that the second mask sheet SH2 is provided, the second mask sheet SH2 may be disposed with a space (e.g., a predetermined or selectable space) spaced from the frame FR in the third direction DR3.

Thereafter, referring to FIG. 7E, a process of providing a second stick ST2 may be performed.

The second stick ST2 may be provided on the frame FR. The second stick ST2 may be disposed in a space between the second mask sheet SH2 and the frame FR.

The second stick ST2 may be disposed in any one stick groove S-H defined in the first long side portion L1 and any one stick groove S-H defined in the second long side portion L2. Thereafter, a rear surface of the second mask sheet SH2 may be disposed to contact the second stick ST2 and the frame FR.

According to an embodiment, a process of tensioning the second stick ST2 may be performed. The tensioning of the second stick ST2 may be performed while the second stick ST2 is provided, or the second stick ST2 may be performed in a state of being tensioned in the second direction DR2. The second stick ST2 may be tensioned by clamps coupled to ends of the second stick ST2.

Thereafter, referring to FIG. 7F, a process of providing a third mask sheet SH3 may be performed.

The third mask sheet SH3 may be provided in a state of being tensioned in the second direction DR2. The third mask sheet SH3 may be tensioned by clamps coupled to ends of the third mask sheet SH3.

In case that the third mask sheet SH3 is provided, the third mask sheet SH3 may be disposed with a space (e.g., a predetermined or selectable space) spaced from the frame FR in the third direction DR3. Thereafter, a rear surface of the third mask sheet SH3 may be disposed to contact the second stick ST2 and the frame FR.

Thereafter, referring to FIG. 7G, a process of forming a coupling sheet SSA may be performed.

The coupling sheet SSA may be formed by coupling the first to third mask sheets SH1, SH2, and SH3 to the first and second sticks ST1 and ST2. The first to third mask sheets SH1, SH2, and SH3 and the first and second sticks ST1 and ST2 may be formed as the coupling sheet SSA having a plate shape by the welding process in the tensioned state.

First welding protrusions WP formed by the welding process may be disposed on the first mask sheet SH1 and the second mask sheet SH2, which overlap the first stick ST1, and first welding protrusions WP formed by the welding process may be disposed on the second mask sheet SH2 and the third mask sheet SH3, which overlap the second stick ST2.

According to this embodiment, as the welding process proceeds in the state in which the first to third mask sheets SH1, SH2, and SH3 and the first and second sticks ST1 and ST2 are tensioned, the welding process may be prevented from proceeding in a sagging state due to its own weight.

In this embodiment, an edge of the coupling sheet SSA may include first to fourth sides A1, A2, A3, and A4. Each of the first to third mask sheets SH1, SH2, and SH3 may include sides spaced apart from each other in the first direction DR1 and other sides spaced apart from each other in the second direction DR2.

The first side A1 may include any one side of the first mask sheet SH1, any one side of the second mask sheet SH2, and any one side of the third mask sheet SH3. The second side A2 may include another side of the first mask sheet SH1, another side of the second mask sheet SH2, and another side of the third mask sheet SH3. The third side A3 may include another side of the first mask sheet SH1. The fourth side A4 may include another side of the third mask sheet SH3.

Thereafter, referring to FIG. 7H, the process of tensioning the coupling sheet SSA may be performed.

The coupling sheet SSA may be tensioned in the first direction DR1 and the second direction DR2. For example, each of the first to fourth sides A1, A2, A3, and A4 of the coupling sheet SSA may be tensioned. The coupling sheet SSA may be tensioned with tensile force stronger than the sum of tensile force applied in the second direction DR2 to the first to third mask sheets SH1, SH2, and SH3 and the first and second sticks ST1 and ST2 described with reference to FIG. 7G.

Thereafter, referring to FIG. 7I, a process of forming pre-deposition openings OP1 in the coupling sheet SSA may be performed.

The pre-deposition openings OP1 may be formed on an area overlapping a frame opening F-OP of the coupling sheet SSA. The pre-deposition openings OP1 respectively provided in the first to third mask sheets SH1, SH2, and SH3 may be formed to pass through front and rear surfaces of the first to third mask sheets SH1, SH2, and SH3.

The pre-deposition openings OP1 may be formed by a laser process, and laser used for the laser process may be any one of millisecond, microsecond, nanosecond, picosecond, and femtosecond laser, but the disclosure is not limited to any one specific embodiment.

According to this embodiment, as the coupling sheet SSA has (or defines) the pre-deposition openings OP1 in the state in which the first to fourth sides A1, A2, A3, and A4 are tensioned, the pre-deposition openings OP1 may be formed at set positions without sagging due to a weight of the coupling sheet SSA itself. Thus, the pre-deposition openings OP1 may be precisely formed in the coupling sheet SSA.

Thereafter, referring to FIG. 7J, a process of adjusting the tensile force of the coupling sheet SSA may be further performed.

The positions of the pre-deposition openings OP1 may be readjusted by adjusting the tensile force of the coupling sheet SSA. The added tensile force is indicated by an additional arrow. The process of adjusting the tensile force may mean that the coupling sheet SSA is additionally tensioned P1 to a side or sides in the first direction DR1 or relieved in tensile force, and the coupling sheet SSA is additionally tensioned P2 to a side or sides in the second direction DR2 or relieved in tensile force.

In the process of adjusting the tensile force, the tension of the coupling sheet SSA may be added or relieved to only a side or sides in one of the first direction DR1 and the second direction DR2. The tension may be added or relieved in a direction diagonal to each of the first and second directions DR1 and DR2.

Thereafter, referring to FIG. 7K, a process of coupling the coupling sheet SSA to the frame FR may be performed.

The coupling sheet SSA may be coupled to the frame FR in the state in which the tensile force is applied. The coupling sheet SSA may be coupled to the frame FR by the laser process. The second welding protrusions WP-S may be formed on the coupling sheet SSA.

According to this embodiment, the coupling sheet SSA may be accurately coupled to a set position of the frame FR as the welding process proceeds on the frame FR in the state in which the tension is applied.

Thereafter, referring to FIG. 7L, a process of releasing the tensile force applied to the coupling sheet SSA is performed.

Even if the tensile force applied to the coupling sheet SSA is released, as illustrated in FIG. 7K, as the coupling sheet SSA is coupled to the frame FR in the state where the tensile force is applied, the coupling sheet SSA may be coupled to the frame FR in a state in which the set positions and processed area of the pre-deposition openings OP1 are maintained.

According to an embodiment, the coupling sheet SSA may be divided into a cutting area CA and a trimming area DA. At least a portion of the trimming area DA may overlap the frame opening F-OP (see FIG. 7A), and the second welding protrusions WP-S may be disposed inside the trimming area DA. The cutting area CA may surround the trimming area DA.

Thereafter, referring to FIGS. 7M and 7N, a process of additionally processing the coupling sheet SSA may be performed. The process of additionally processing the coupling sheet SSA may include trimming processes.

Referring to FIG. 7M, in a first trimming process, widths of the coupling sheet SSA in the first direction DR1 and the second direction DR2 may be adjusted by removing a portion of the coupling sheet SSA. For example, the first trimming process may be a process of cutting the first to third mask sheets SH1, SH2, and SH3 so that at least an area, exposed from the frame FR, of the coupling sheet SSA is removed. The cutting area CA may be removed from the coupling sheet SSA of FIG. 7L. The state in which the cutting area CA is removed from the coupling sheet SSA of FIG. 7L may be defined as the trimming sheet SS.

The mask assembly MSA according to an embodiment may include a trimming sheet SS coupled to the frame FR.

Referring to FIG. 7N, a second trimming process may be a process of trimming the pre-deposition openings OP1.

In the second trimming process, deposition openings OP each of which has an area greater than that of each of the pre-deposition openings OP1 may be formed by irradiating (or emitting) laser to the pre-deposition openings OP1. However, the embodiment of the disclosure is not limited thereto, and in the second trimming process, an inner surface of the trimming sheet SS defining each of the pre-deposition openings OP1 may be processed into an inclined surface. A process of removing residues (or particles) generated in the process of forming the pre-deposition openings OP1 may be performed.

According to an embodiment, the second trimming process may be performed immediately after forming the pre-deposition openings OP1, but is not limited to any one specific embodiment.

In the method for manufacturing the mask assembly according to the disclosure, the deposition openings OP may be formed in the first to third mask sheets SH1, SH2, and SH3, and the deposition openings may have various sizes. The first to third mask sheets SH1, SH2, and SH3 and the first and second sticks ST1 and ST2 may be coupled to the frame FR in the tensioned state to manufacture the mask assembly MSA in which the sagging phenomenon is reduced.

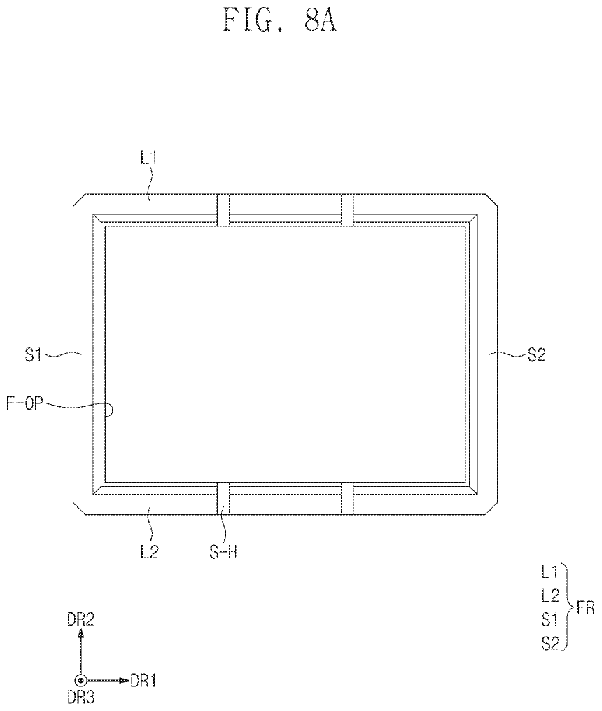

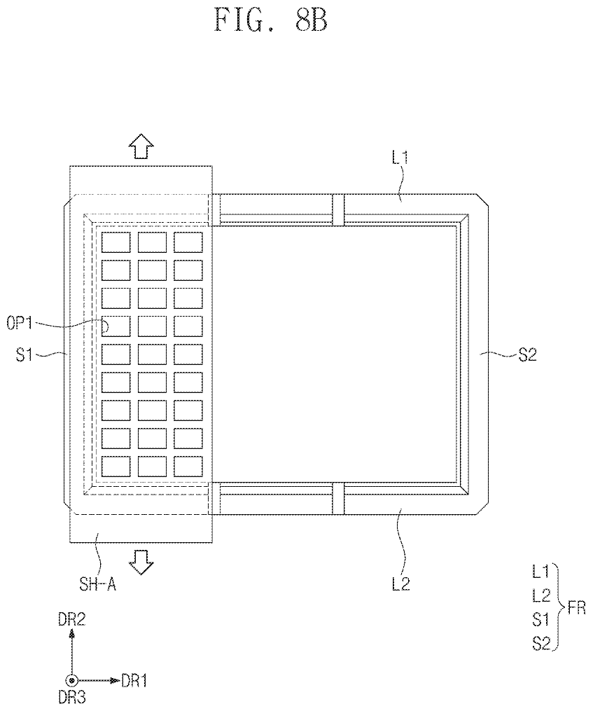

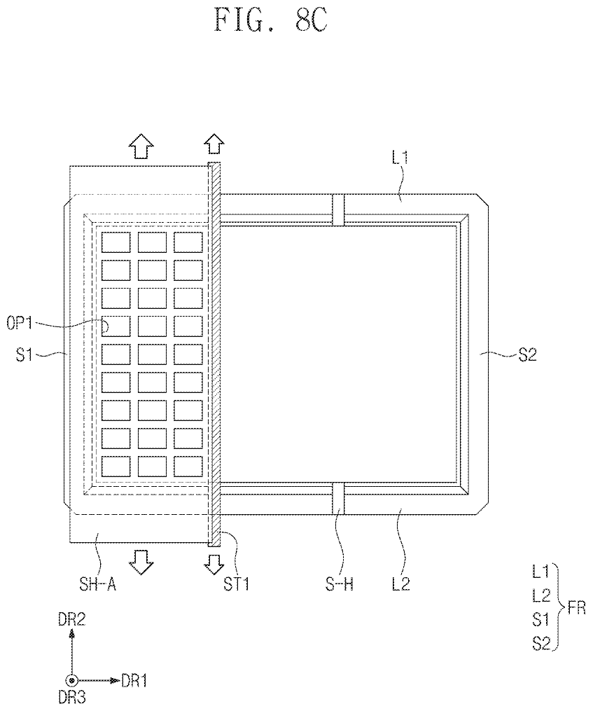

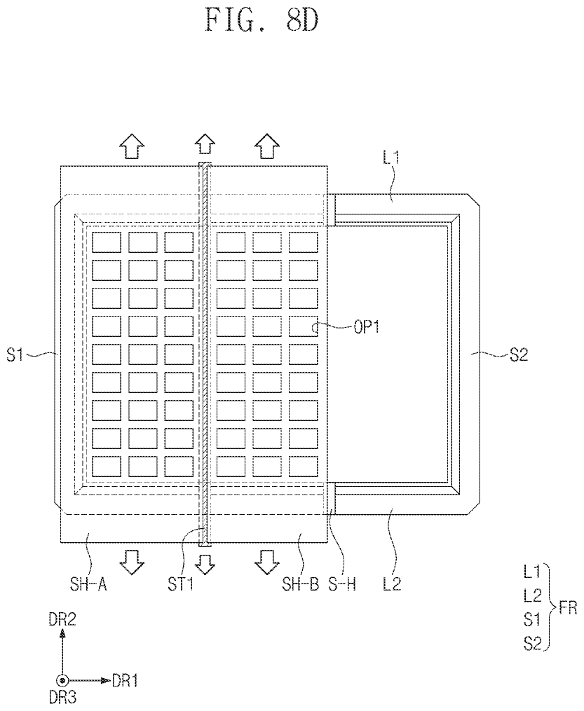

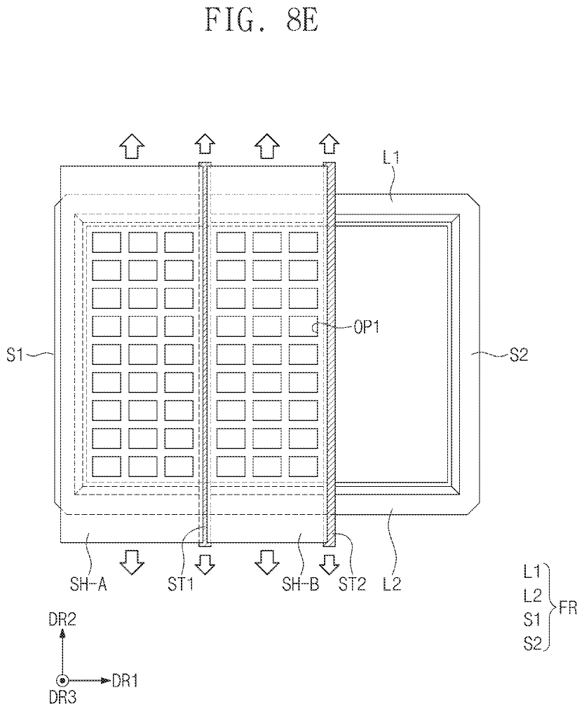

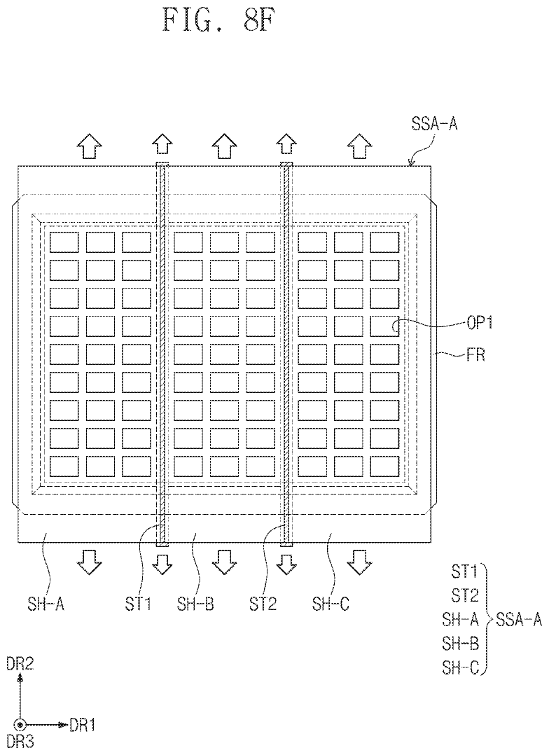

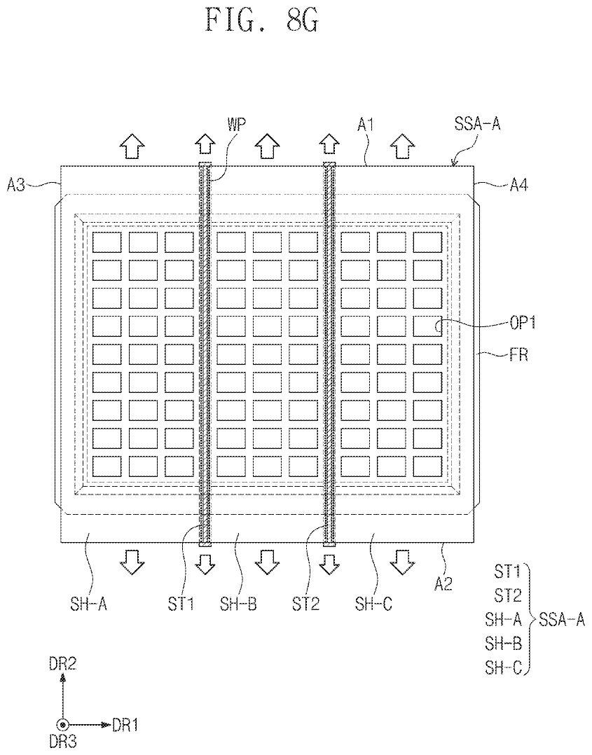

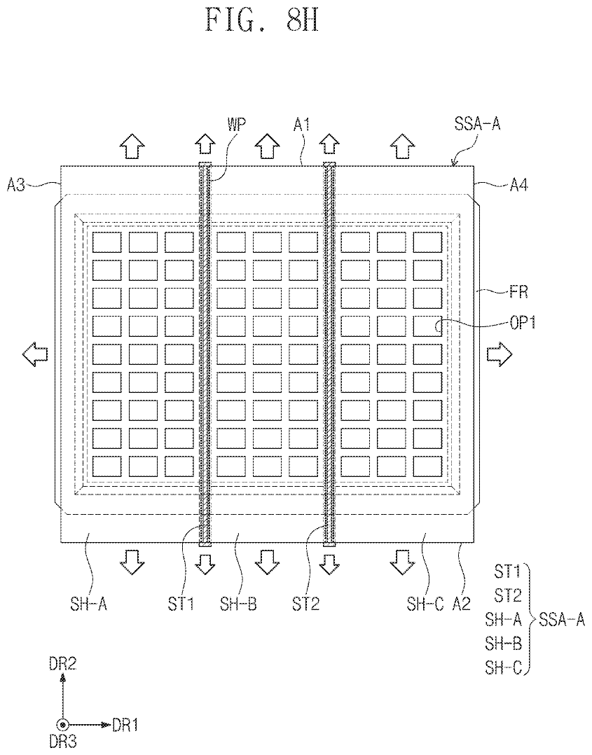

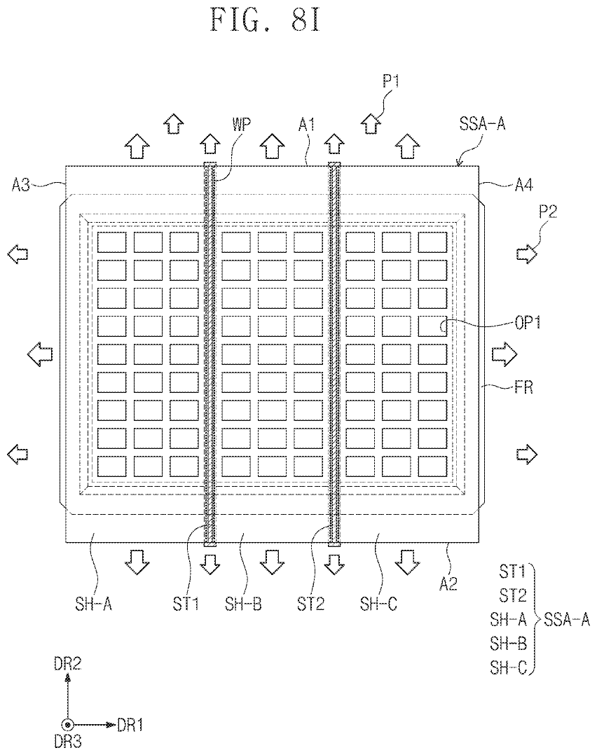

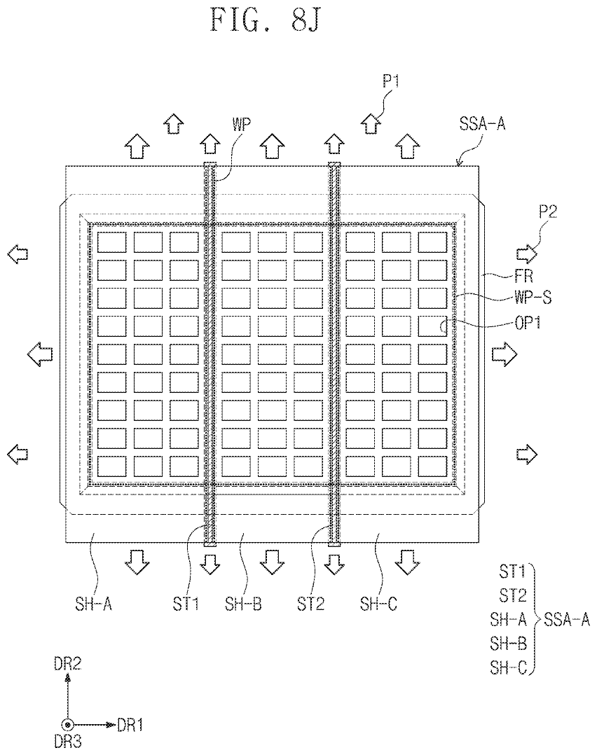

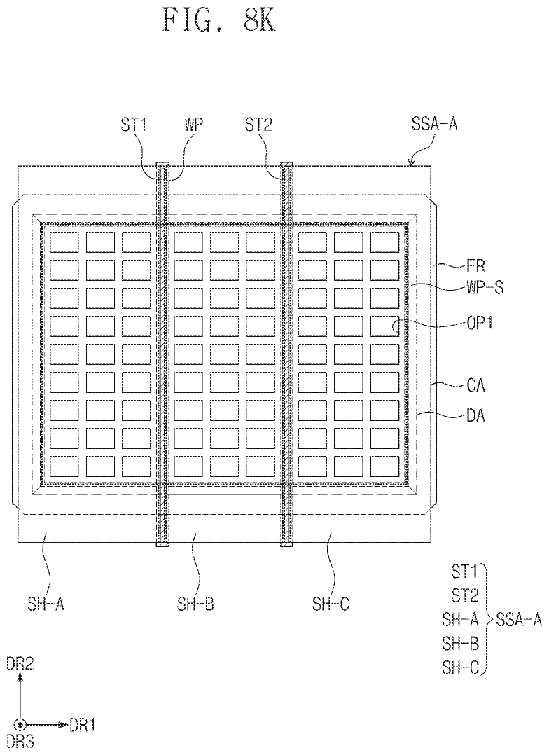

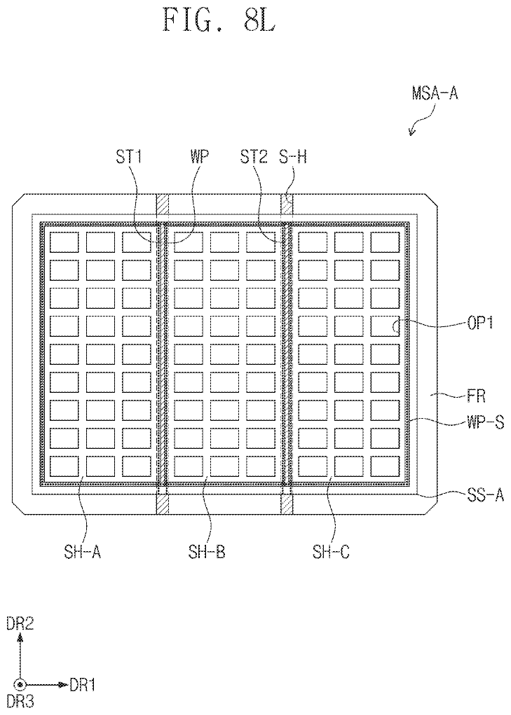

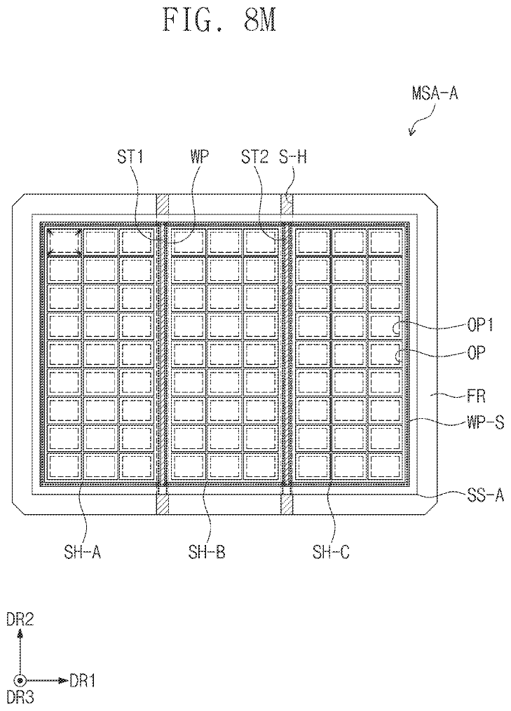

FIGS. 8A to 8M are schematic plan views illustrating a method for manufacturing a mask assembly according to an embodiment of the disclosure. The same or similar reference numerals are used for the same or similar components as those described in FIGS. 1 to 4B and 7A to 7N, and repeated descriptions are omitted.

A method for manufacturing a mask assembly according to an embodiment may include a process of providing a frame in which a frame opening is defined and of which a width in a first direction is greater than that in a second direction intersecting the first direction, a process of providing mask sheets and at least one stick, which supports two adjacent mask sheets among the mask sheets, on the frame, a process of forming a coupling sheet by coupling the mask sheets adjacent to the at least one stick to the at least one stick in a state in which the mask sheets and the at least one stick are tensioned to sides (or both sides) thereof in the second direction, a process of tensioning the coupling sheet to sides (or the both sides) thereof in the first direction and tensioning the coupling sheet to sides (or the both sides) in the second direction, a process of coupling the tensioned coupling sheet to the frame, a process of releasing tensile force applied to the coupling sheet, to which the frame is coupled, and a process of additionally processing the coupling sheet from which the tensile force is released and may further include a process of forming pre-deposition openings in the mask sheets, respectively. The process of forming the pre-deposition openings may be performed before the process of providing the mask sheets on the frame.

Hereinafter, a method of manufacturing a mask assembly MSA-A according to an embodiment will be described in more detail with reference to FIGS. 8A to 8M.

Referring to FIG. 8A, a process of providing a frame FR may be performed. The frame FR may include long side portions L1 and L2 and short side portions S1 and S2, which are connected to each other to define a frame opening F-OP.

Thereafter, referring to FIG. 8B, a process of providing a first mask sheet SH-A may be provided.

The first mask sheet SH-A may be provided in a state of being tensioned in the second direction DR2. The first mask sheet SH-A may be tensioned by clamps coupled to ends of the first mask sheet SH-A.

In this embodiment, the first mask sheet SH-A may be provided in a state in which pre-deposition openings OP1 are formed. The pre-deposition openings OP1 may be provided in plurality and arranged to be spaced apart from each other in the first direction DR1 and the second direction DR2.

In case that the first mask sheet SH-A is provided, the first mask sheet SH-A may be disposed with a space (e.g., a predetermined or selectable space) spaced from the frame FR at a space in the third direction DR3.

Thereafter, referring to FIG. 8C, a process of providing a first stick ST1 may be performed.

The first stick ST1 may be provided on the frame FR. The first stick ST1 may be disposed in a space between the first mask sheet SH1 and the frame FR.

The first stick ST1 may be disposed in any one stick groove S-H defined in a first long side portion L1 and any one stick groove S-H defined in a second long side portion L2. Thereafter, a rear surface of the first mask sheet SH1 may be disposed to contact the first stick ST1 and the frame FR.

According to an embodiment, a process of tensioning the first stick ST1 may be performed. The tensioning of the first stick ST1 may be performed while the first stick ST1 is provided, or the first stick ST1 may be provided in a state of being tensioned in the second direction DR2. The first stick ST1 may be tensioned by clamps coupled to ends of the first stick ST1.

Thereafter, referring to FIG. 8D, a process of providing a second mask sheet SH-B may be performed. The second mask sheet SH-B may be provided in a state of being tensioned in the second direction DR2. The second mask sheet SH-B may be tensioned by clamps coupled to ends of the second mask sheet SH-B.

In this embodiment, the second mask sheet SH-B may be provided in a state in which pre-deposition openings OP1 are formed. The pre-deposition openings OP1 may be provided in plurality and arranged to be spaced apart from each other in the first direction DR1 and the second direction DR2.

In case that the second mask sheet SH-B is provided, the second mask sheet SH-B may be disposed with a space (e.g., a predetermined or selectable space) spaced from the frame FR at a space in the third direction DR3.

Thereafter, referring to FIG. 8E, a process of providing a second stick ST2 may be performed.

The second stick ST2 may be provided on the frame FR. The second stick ST2 may be disposed in a space between the second mask sheet SH-B and the frame FR.

The second stick ST2 may be disposed in any one stick groove S-H defined in the first long side portion L1 and any one stick groove S-H defined in the second long side portion L2. Thereafter, a rear surface of the second mask sheet SH-B may be disposed to contact the second stick ST2 and the frame FR.

According to an embodiment, a process of tensioning the second stick ST2 may be performed. The tensioning of the second stick ST2 may be performed in a state in which the second stick ST2 is provided, or may be performed in a state in which the second stick ST2 is tensioned in the second direction DR2. The second stick ST2 may be tensioned by clamps coupled to ends of the second stick ST2.

Thereafter, referring to FIG. 8F, a process of providing a third mask sheet SH-C may be performed.

The third mask sheet SH-C may be provided in a state of being tensioned in the second direction DR2. The third mask sheet SH-C may be tensioned by clamps coupled to ends (or both ends) of the third mask sheet SH-C.

In this embodiment, the third mask sheet SH-C may be provided in a state in which pre-deposition openings OP1 are formed. The pre-deposition openings OP1 may be provided in plurality and arranged to be spaced apart from each other in the first direction DR1 and the second direction DR2.

In case that the third mask sheet SH-C is provided, the third mask sheet SH-C may be disposed with a space (e.g., a predetermined or selectable space) spaced from the frame FR at space in the third direction DR3. Thereafter, a rear surface of the third mask sheet SH-C may be disposed to contact the second stick ST2 and the frame FR.

According to this embodiment, since the first to third mask sheets SH-A, SH-B, and SH-C are provided on the frame in the state in which the pre-deposition openings OP1 are formed in the first to third mask sheets SH-A, SH-B, and SH-C, a separate process of forming the pre-deposition openings OP1 may be omitted.

Thereafter, referring to FIG. 8G, a process of forming a coupling sheet SSA-A may be performed.

The coupling sheet SSA-A may be formed by coupling the first to third mask sheets SH-A, SH-B, and SH-C to the first and second sticks ST1 and ST2. The first to third mask sheets SH-A, SH-B, and SH-C and the first and second sticks ST1 and ST2 may be formed as the coupling sheet SSA-A having a plate shape by the welding process in the tensioned state.

First welding protrusions WP formed by the welding process may be disposed on the first mask sheet SH-A and the second mask sheet SH-B, which overlap the first stick ST1, and first welding protrusions WP formed by the welding process may be disposed on the second mask sheet SH-B and the third mask sheet SH-C, which overlap the second stick ST2.

In this embodiment, an edge of the coupling sheet SSA-A may include first to fourth sides A1, A2, A3, and A4. Each of the first to third mask sheets SH-A, SH-B, and SH-C may include sides spaced apart from each other in the first direction DR1 and other sides spaced apart from each other in the second direction DR2.

The first side A1 may include any one side of the first mask sheet SH-A, any one side of the second mask sheet SH-B, and any one side of the third mask sheet SH-C. The second side A2 may include another side of the first mask sheet SH-A, another side of the second mask sheet SH-B, and another side of the third mask sheet SH-C. The third side A3 may include another side of the first mask sheet SH-A. The fourth side A4 may include another side of the third mask sheet SH-C.

Thereafter, referring to FIG. 8H, a process of tensioning the coupling sheet SSA-A may be performed.

The coupling sheet SSA-A may be tensioned in the first direction DR1 and the second direction DR2. For example, each of the first to fourth sides A1, A2, A3, and A4 of the coupling sheet SSA may be tensioned. The coupling sheet SSA-A may be tensioned with tensile force stronger than the sum of tensile force applied in the second direction DR2 to the first to third mask sheets SH-A, SH-B, and SH-C and the first and second sticks ST1 and ST2 described with reference to FIG. 8G.

Thereafter, referring to FIG. 8I, a process of adjusting the tensile force of the coupling sheet SSA-A may be further performed.

The positions of the pre-deposition openings OP1 may be readjusted by adjusting the tensile force of the coupling sheet SSA-A. The added tensile force is indicated by an additional arrow. The process of adjusting the tensile force may mean that the coupling sheet SSA-A is additionally tensioned P1 to a side or sides thereof in the first direction DR1 or relieved in tensile force, and the coupling sheet SSA-A is additionally tensioned P2 to a side or sides thereof in the second direction DR2 or relieved in tensile force.

In the process of adjusting the tensile force, the tension of the coupling sheet SSA-A may be added or relieved to only a side or sides in one of the first direction DR1 and the second direction DR2. The tension may be added or relieved in a direction diagonal to each of the first and second directions DR1 and DR2.

Thereafter, referring to FIG. 8J, a process of coupling the coupling sheet SSA-A to the frame FR may be performed.

The coupling sheet SS-A may be coupled to the frame FR in the state in which the tensile force is applied. The coupling sheet SSA-A may be coupled to the frame FR by the laser process. The second welding protrusions WP-S may be formed on the coupling sheet SSA-A.

According to this embodiment, the coupling sheet SSA-A may be accurately coupled to a set position of the frame FR as the welding process proceeds on the frame FR in the state in which the tension is applied.

Thereafter, referring to FIG. 8K, a process of releasing the tensile force applied to the coupling sheet SSA-A is performed.

Even if the tensile force applied to the coupling sheet SS-A is released, as illustrated in FIG. 8K, as the coupling sheet SSA-A is coupled to the frame FR in the state where the tensile force is applied, the coupling sheet SSA-A may be coupled to the frame FR in a state in which the set positions and processed area of the pre-deposition openings OP1 are maintained.

According to an embodiment, the coupling sheet SSA-A may be divided into a cutting area CA and a trimming area DA. At least a portion of the trimming area DA may overlap the frame opening F-OP (see FIG. 8A), and the second welding protrusions WP-S may be disposed inside the trimming area DA. The cutting area CA may surround the trimming area DA.

Thereafter, referring to FIGS. 8L and 8M, a process of additionally processing the coupling sheet SSA-A may be performed. The process of additionally processing the coupling sheet SSA-A may include trimming processes.

Referring to FIG. 8L, in a first trimming process, widths of the coupling sheet SSA-A in the first direction DR1 and the second direction DR2 may be adjusted by removing a portion of the coupling sheet SSA-A. For example, the first trimming process may be a process of cutting the first to third mask sheets SH1, SH2, and SH3 so that at least an area, exposed from the frame FR, of the coupling sheet SSA-A is removed. The cutting area CA may be removed from the coupling sheet SSA-A of FIG. 8K. The state in which the cutting area CA is removed from the coupling sheet SSA-A of FIG. 8K may be defined as a trimming sheet SS-A.

The mask assembly MSA-A according to an embodiment may include a trimming sheet SS-A coupled to the frame FR.

Referring to FIG. 8M, the second trimming may be a process of trimming the pre-deposition openings OP1.

In the second trimming process, deposition openings OP each of which has an area greater than that of each of the pre-deposition openings OP1 may be formed by irradiating laser at the pre-deposition openings OP1. However, the embodiment of the disclosure is not limited thereto, and in the second trimming process, an inner surface of the trimming sheet SS-A defining each of the pre-deposition openings OP1 may be processed into an inclined surface. A process of removing residues (or particles) generated in the process of forming the pre-deposition openings OP1 may be performed.

The mask assembly according to the disclosure may include a type of stick to reduce the shadow defect phenomenon of the deposition layer, which occurs on the area on which the existing sticks cross each other. The small number of sticks may be provided to reduce the risk of the deposition defects occurring due to the stick deformation.

In addition, in the method for manufacturing the mask assembly according to the disclosure, the deposition openings may be defined in the mask sheet, and also, the deposition openings having the various sizes may be defined. In the state in which the mask sheets and the sticks are tensioned, the mask sheets and the sticks may be coupled to the frame to manufacture the mask assembly having the reduced sagging phenomenon.

In addition, in the method for manufacturing the display panel by using the mask assembly, the display panel including the deposition layer having the improved precision and uniform thickness may be manufactured using the above-described mask assembly.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A mask assembly comprising:
a frame comprising:
long side portions extending in a first direction and spaced apart from each other in a second direction intersecting the first direction; and
short side portions connected to the long side portions, the frame defining a frame opening;
a first stick extending in the second direction and connected to the frame;
a first mask sheet defining first deposition openings and connected to the first stick and the frame, at least part of the first deposition openings arranged in the first direction and overlapping the frame opening in a plan view; and
a second mask sheet defining second deposition openings and connected to the first stick and the frame, at least part of the second mask sheet arranged in the first direction and overlapping the frame opening in a plan view.

2. The mask assembly of claim 1, wherein a portion of the first stick is exposed between the first mask sheet and the second mask sheet.

3. The mask assembly of claim 1, wherein
the long side portions include stick grooves , and
the first stick is inserted into the stick grooves.

4. The mask assembly of claim 1, wherein the first stick is disposed on a rear surface of the first mask sheet and a rear surface of the second mask sheet.

5. The mask assembly of claim 1, wherein the first stick is disposed on a front surface of the first mask sheet and a front surface of the second mask sheet.

6. The mask assembly of claim 1, wherein each of the first mask sheet and the second mask sheet has a thickness in a range of about 50 um to about 300 um.

7. The mask assembly of claim 1, wherein
the first stick has a thickness in a range of about 50 um to about 300 um, and
the first stick in the first direction has a width in a range of about 1 mm to about 5 mm.

8. The mask assembly of claim 1, wherein each of the first mask sheet, the second mask sheet, the first stick, and the frame comprises an invar.

9. The mask assembly of claim 1, further comprising:
a second stick extending in the second direction and spaced apart from the first stick in the first direction; and
a third mask sheet defining third deposition openings and connected to the second stick and the frame, the third deposition openings arranged in the first direction and overlapping the frame opening in a plan view, wherein
the second mask sheet is disposed between the first mask sheet and the third mask sheet, and
a portion of the second stick is exposed between the second mask sheet and the third mask sheet.

10. The mask assembly of claim 9, wherein
each of the first to third mask sheets comprises sides spaced apart from each other in the first direction and other sides spaced apart from each other in the second direction,
one of the sides of the first mask sheet is connected to the first stick, another one of the sides is connected to an overlapping one of the short side portions, and each of the other sides is connected to an overlapping one of the long side portions,
one of the sides of the third mask sheet is connected to the second stick, another one of the sides is connected to an overlapping one of the short side portions, and each of the other sides is connected to an overlapping one of the long side portions, and
one of the sides of the second mask sheet is connected to the first stick, another one of the sides is connected to the second stick, and each of the other sides is connected to an overlapping one of the long side portions.

11. The mask assembly of claim 10, further comprising:
first welding protrusions respectively disposed on a front surface of each of the first mask sheet and the second mask sheet and a front surface of the second mask sheet and the third mask sheet, the front surface of each of the first mask sheet and second mask sheet overlapping the first stick in a plan view, the front surface of each of the second mask sheet and third mask sheet overlapping the second stick in a plan view; and
second welding protrusions respectively disposed on the front surfaces of the first to third mask sheets overlapping the frame in a plan view.

12. The mask assembly of claim 9, wherein at least one of the first deposition openings, the second deposition openings, and the third deposition openings is arranged in n rows×m columns in the first direction and the second direction, n and m being natural numbers and at least one of n and m being greater than or equal to 2.

13. The mask assembly of claim 1, wherein a width of each of the first mask sheet and the second mask sheet in the first direction is less than a width of each of the first mask sheet and the second mask sheet in the second direction.

14. A method for manufacturing a mask assembly, the method comprising:
providing a frame defining a frame opening, a width of the frame in a first direction is greater than a width of the frame in a second direction intersecting the first direction;
providing mask sheets and at least one stick on the frame, the at least one stick supporting two adjacent ones of the mask sheets;
connecting the mask sheets adjacent to the at least one stick to the at least one stick in a state in which the mask sheets and the at least one stick are tensioned to sides in the second direction;
tensioning the coupling sheet to sides in the first direction and tensioning the coupling sheet to the sides in the second direction by applying tensile force;
connecting the tensioned coupling sheet to the frame;
releasing the tensile force applied to the coupling sheet to which the frame is connected; and
additionally processing the coupling sheet from which the tensile force is released, wherein
the method further comprises forming pre-deposition openings in each of the mask sheets, and
the forming of the pre-deposition openings is performed before the providing of the mask sheets on the frame or performed between the tensioning of the coupling sheet and the connecting of the tensioned coupling sheet to the frame.

15. The method of claim 14, wherein
the mask sheets comprise first to third mask sheets,
the at least one stick comprises:
a first stick overlapping the first mask sheet and the second mask sheet in a plan view; and
a second stick overlapping the second mask sheet and the third mask sheet in a plan view,
the providing of the mask sheets and the at least one stick comprises sequentially providing the first mask sheet, the first stick, the second mask sheet, the second stick, and the third mask sheet.

16. The method of claim 15, wherein the pre-deposition openings are arranged to be spaced apart from each other in the first direction and the second direction.

17. The method of claim 14, wherein, in the providing of the mask sheets and the at least one stick, the mask sheets and the at least one stick are provided to sides in the second direction in a state in which each of the mask sheets and the at least one stick is tensioned.

18. The method of claim 14, wherein the forming of the coupling sheet comprises welding each of the mask sheets to a corresponding one of the at least one stick.

19. The method of claim 14, wherein the connecting of the tensioned coupling sheet to the frame comprises welding the coupling sheet to the frame.

20. The method of claim 14, further comprising:
adjusting the tensile force applied to the coupling sheet between the tensioning of the coupling sheet and the connecting of the tensioned coupling sheet to the frame.

21. The method of claim 14, wherein the forming of the pre-deposition openings is performed by a laser process.

22. The method of claim 14, wherein the additionally processing of the coupling sheet from which the tensile force is released comprises cutting the mask sheets to remove an exposed area from at least the frame.

23. The method of claim 14, wherein the additionally processing of the coupling sheet from which the tensile force is released comprises trimming the pre-deposition openings to form deposition openings.

24. The method of claim 23, wherein each of the deposition openings has a surface area greater than a surface area of each of the pre-deposition openings.

25. A method for manufacturing a mask assembly, the method comprising:
forming a deposition layer on a deposition substrate with the mask assembly, wherein the mask assembly comprises:
a frame comprising:
long side portions extending in a first direction and spaced apart from each other in a second direction intersecting the first direction; and
short side portions connected to the long side portions, the frame defining a frame opening;
a first stick extending in the second direction and connected to the frame;
a first mask sheet defining first deposition openings arranged to be spaced apart from each other in the first direction and overlapping the frame opening in a plan view, the first mask sheet being connected to the first stick and the frame; and
a second mask sheet defining second deposition openings arranged to be spaced apart from each other in the first direction and overlapping the frame opening in a plan view, the second mask sheet being connected to the first stick and the frame.

26. The method of claim 25, wherein
the deposition substrate comprises unit areas and a non-deposition area adjacent to the unit areas,
each of the unit areas overlaps a corresponding opening of the first deposition openings and the second deposition openings in a plan view, and
the non-deposition area overlaps the first mask sheet, the first stick, and the second mask sheet in a plan view.

27. The method of claim 26, wherein
light emitting elements are disposed in each of the unit areas,
each of the light emitting elements comprises a first electrode, a second electrode, and a light emitting layer between the first electrode and the second electrode,
the light emitting layer corresponds to the deposition layer formed by deposition vapor passing through the corresponding opening, and
the light emitting layer of each of the light emitting elements has an integral shape.

28. The method of claim 26, wherein
light emitting elements are disposed in each of the unit areas,
at least one inorganic layer is disposed on a lower portion or an upper portion of each of the light emitting elements,
the at least one inorganic layer corresponds to the deposition layer formed by deposition vapor passing through the corresponding opening, and
the at least one inorganic layer has an integral shape.
